(19) United States
(12) Patent Application Publication
(10) Pub. No.: US 2026/0371765 A1
(43) Pub. Date: Nov. 19, 2026

(54) IMAGE SENSOR DEVICE AND METHODS OF FORMATION

(71) Applicant: Taiwan Semiconductor Manufacturing Company, Ltd., Hsinchu (TW)

(72) Inventors: Tsung-Yu LEE, Tainan City (TW); Ming-Chyi LIU, Hsinchu City (TW)

(21) Appl. No.: 19/749,725

(22) Filed: Jul. 22, 2026

Related U.S. Application Data
(62) Division of application No. 18/587,813, filed on Feb. 26, 2024.

(51) Int. Cl. H10F 39/00; H10F 39/18

(52) U.S. Cl. CPC H10F 39/807; H10F 39/011; H10F 39/182

(57) ABSTRACT

Dielectric regions are formed in a semiconductor substrate of a semiconductor device. The dielectric regions may be formed in locations above which cross-road portions of a backside deep trench isolation (BDTI) structure are to be formed for a pixel sensor array of the semiconductor device. The dielectric regions may function as etch stop structures in the cross-road portions when etching the semiconductor substrate to form the trenches in which the BDTI structure is to be formed. In particular, the dielectric regions minimize and/or prevent the increase in trench depth of the trenches in the cross-road portions relative to the trench depth of the trenches in the non-cross-road portions.

### RELATED APPLICATION

This application is a divisional of U.S. Patent Application No. 18/587,813, filed Feb. 26, 2024, which is incorporated herein by reference in its entirety.

### BACKGROUND

A complementary metal oxide semiconductor (CMOS) image sensor (CIS) may include a plurality of pixel sensors. A pixel sensor of the CMOS image sensor may include a transfer gate transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example of a pixel sensor described herein.

FIGS. 3A and 3B are diagrams of an example implementation of a pixel sensor array described herein.

FIGS. 4A and 4B are diagrams of an example implementation of a portion of a pixel sensor array described herein.

FIGS. 5A-5N are diagrams of an example implementation of forming a pixel sensor array of the image sensor device described herein.

FIGS. 6A-6G are diagrams of an example implementation of forming a pixel sensor array of the image sensor device described herein.

FIG. 7 is a diagram of example components of a device described herein.

FIG. 8 is a flowchart of an example process associated with forming an image sensor device described herein.

FIG. 9 is a flowchart of an example process associated with forming an image sensor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Pixel sensors in a pixel sensor array are often separated by trench isolation structures. For example, a backside deep trench isolation (BDTI) structure may electrically and/or optically isolate pixel sensors in a pixel sensor array. The BDTI structure may include a grid of intersecting trenches arranged around the pixel sensors. Some regions of the BDTI structure (referred to as non-cross-road portions or non-X-road portions) may border (or may be included between) one or two pixel sensors in the pixel sensor array. Other regions (referred to as cross-road portions or X-road portions) of the BDTI structure may be located at an intersection between corners of three or more pixel sensors in the pixel sensor array.

An etch rate for etching recesses for the BDTI structure at cross-road portions generally may be greater relative to an etch rate for etching recesses at non-cross-road portions of the BDTI structures due to the greater spacing (sometimes referred to as “critical dimension” or “CD”) between the photodiodes in the cross-road portions than in the non-cross-road portions. The increase in spacing results from a greater area in which etchant is provided, resulting in a greater amount of etchant in the cross-road portions than in the non-cross-road portions. The greater amount of etchant results in the greater etch rate in the cross-road portions than in the non-cross-road portions, resulting in increased trench depth loading in the cross-road portions. “Trench depth loading” refers to a greater depth of etching in the cross-road portions than in the non-cross-road portions. The increased trench depth loading may increase the likelihood of etching into floating diffusion nodes in the cross-road portion, which may damage the floating diffusion nodes of the pixel sensors and result in failure of the pixel sensors.

In some implementations described herein, dielectric regions are formed in a semiconductor substrate of a semiconductor device. The dielectric regions may be formed in locations above which cross-road portions of a BDTI structure are to be formed for a pixel sensor array of the semiconductor device. The dielectric regions may function as etch stop structures in the cross-road portions when etching the semiconductor substrate to form the trenches in which the BDTI structure is to be formed. In particular, the dielectric regions minimize and/or prevent the increase in trench depth of the trenches in the cross-road portions relative to the trench depth of the trenches in the non-cross-road portions.

In this way, the dielectric regions reduce and/or minimize trench depth loading in the cross-road portions of the trenches. Thus, the dielectric regions prevent, minimize, and/or reduce the likelihood of etching into floating diffusion nodes of pixel sensors of the pixel sensor array, which reduces the likelihood of degraded performance and/or failure of the pixel sensors.

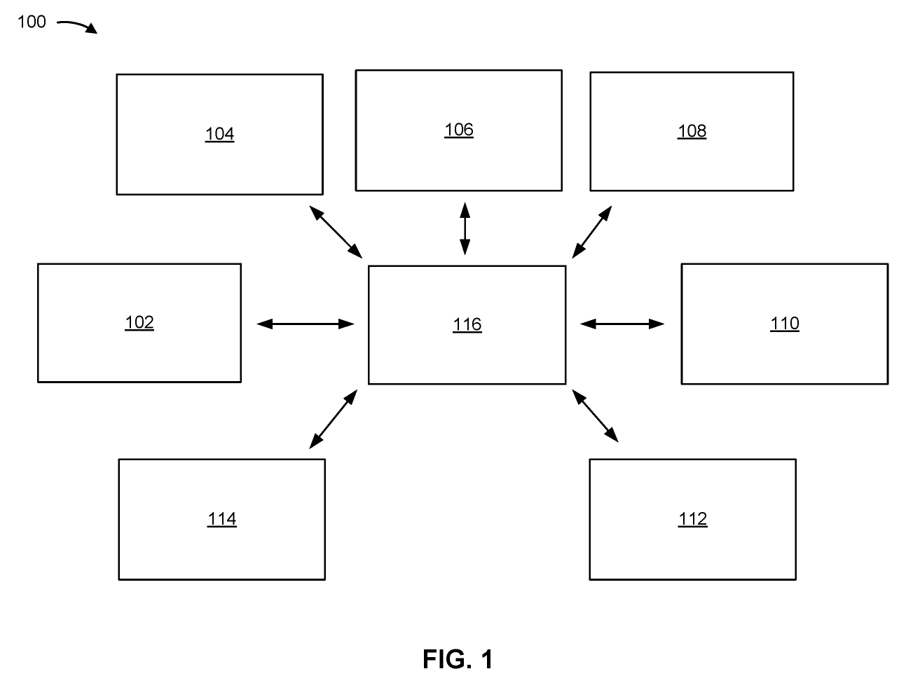

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device ﬂat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-114 and/or the wafer/die transport tool 116 may be used to perform one or more semiconductor processing operations described herein. For example, one or more of the semiconductor processing tools 102-114 and/or the wafer/die transport tool 116 may be used to form, from a first surface of a semiconductor layer of an image sensor device, a dielectric etch stop structure in the semiconductor layer; form, from the first surface of the semiconductor layer, a floating diffusion node above the dielectric etch stop structure in the semiconductor layer; and/or etch the semiconductor layer, from a second surface of the semiconductor layer opposing the first surface, to form a plurality of intersecting trenches in the semiconductor layer after forming the floating diffusion node, where two or more of the intersecting trenches intersect in a cross-road portion above the dielectric etch stop structure and the floating diffusion node, and where the etching of the semiconductor layer stops on the dielectric etch stop structure in the cross-road portion, among other examples.

As another example, one or more of the semiconductor processing tools 102-114 and/or the wafer/die transport tool 116 may be used to form, from a first surface of a semiconductor layer of an image sensor device, a plurality of photodiodes in the semiconductor layer; form, from the first surface, a dielectric etch stop structure adjacent to the plurality of photodiodes in the semiconductor layer, where a distance between the dielectric etch stop structure and the first surface is less than a distance between the plurality of photodiodes and the first surface; form, from the first surface of the semiconductor layer, a floating diffusion node above the dielectric etch stop structure in the semiconductor layer; etch the semiconductor layer, from a second surface of the semiconductor layer opposing the first surface, to form a plurality of intersecting trenches in the semiconductor layer after forming the floating diffusion node, where two or more of the intersecting trenches intersect in a cross-road portion above the dielectric etch stop structure and the floating diffusion node, and where the etching of the semiconductor layer stops on the dielectric etch stop structure in the cross-road portion; and/or form a BDTI structure in the plurality of intersecting trenches, where a portion of the BDTI structure, in the cross-road portion, is formed on the dielectric etch stop structure, among other examples.

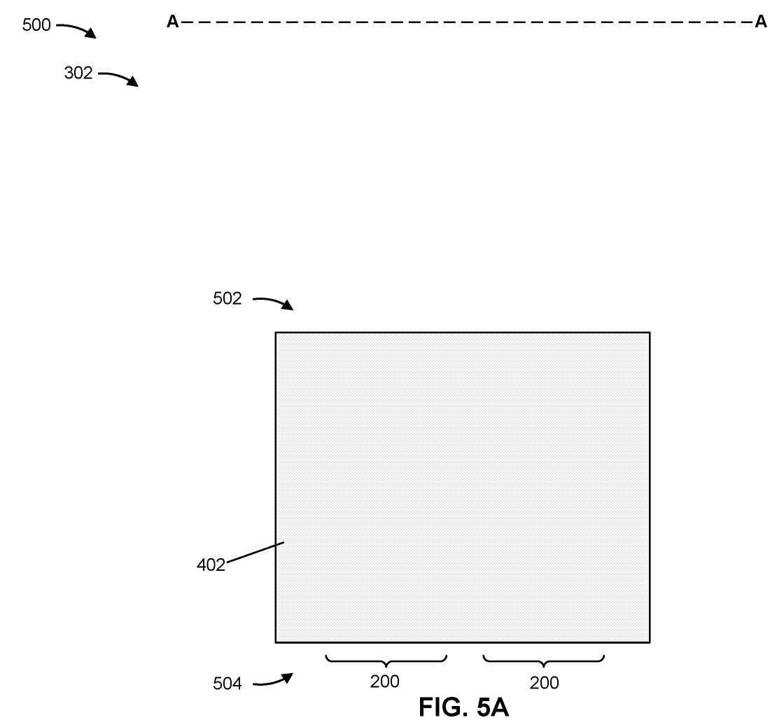

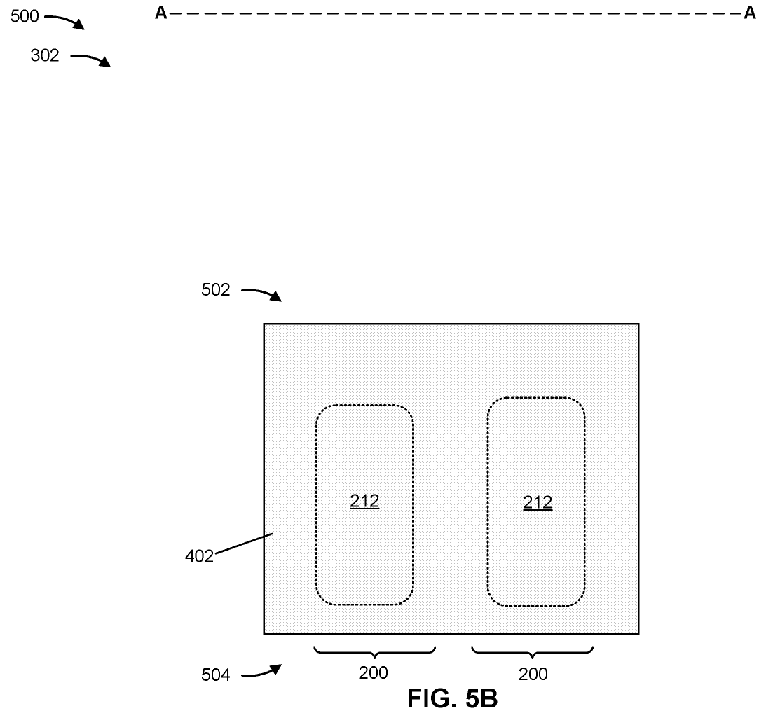

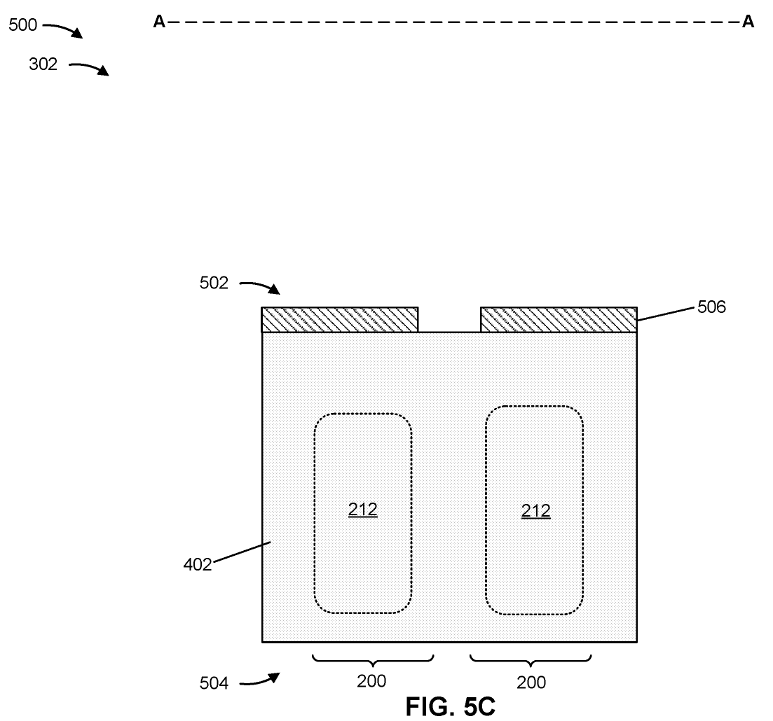

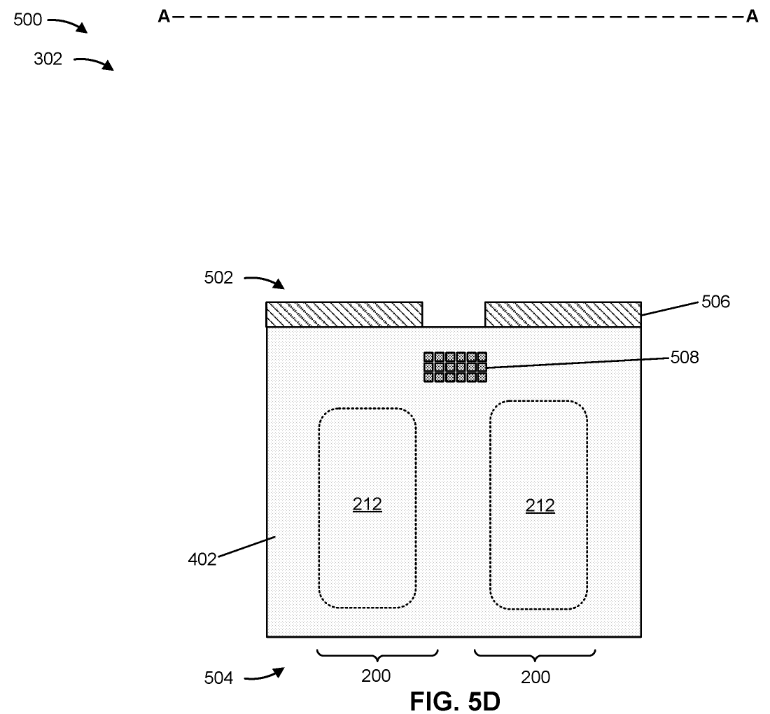

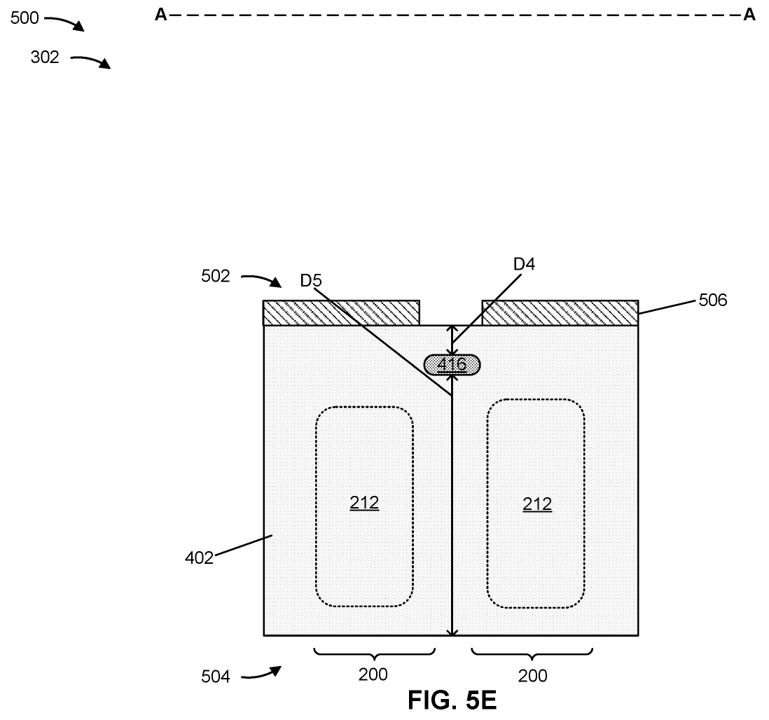

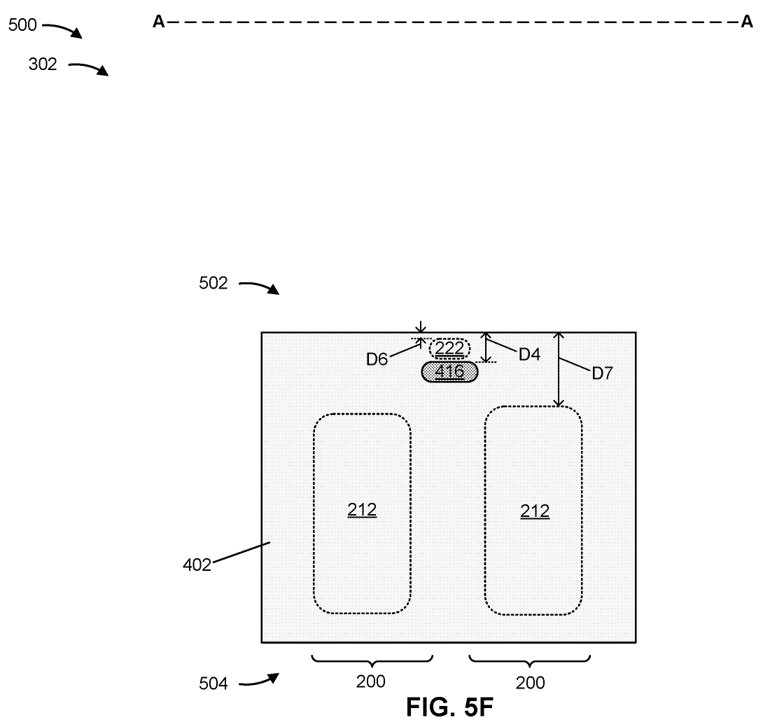

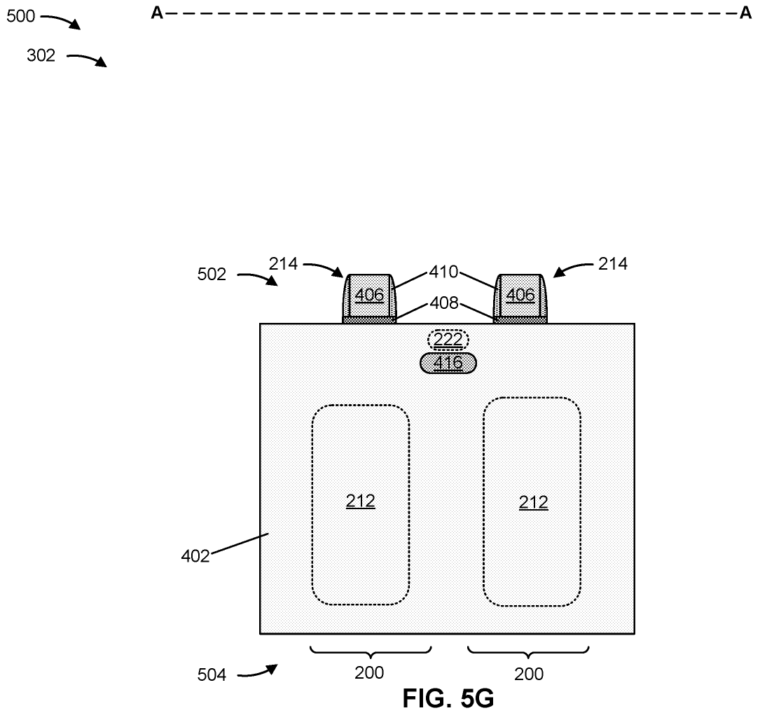

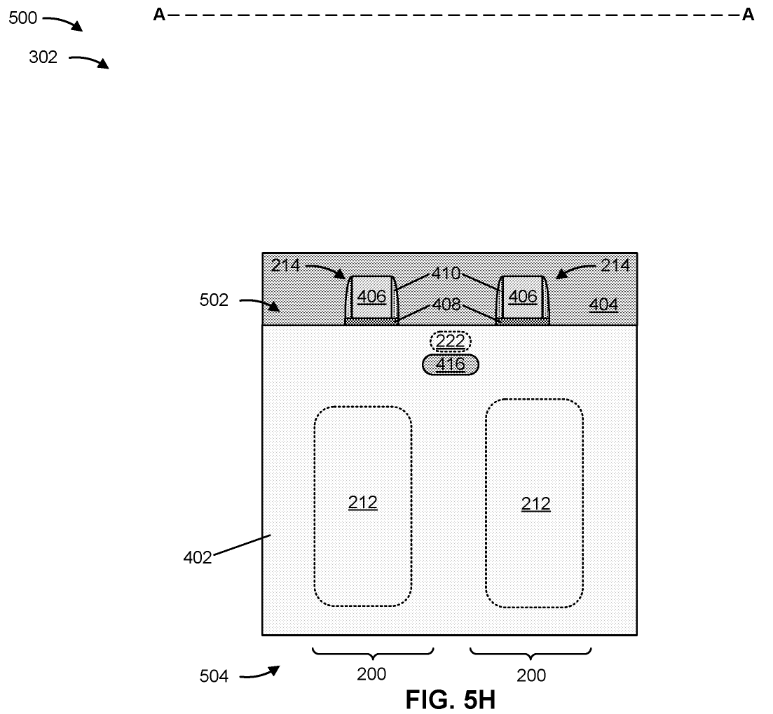

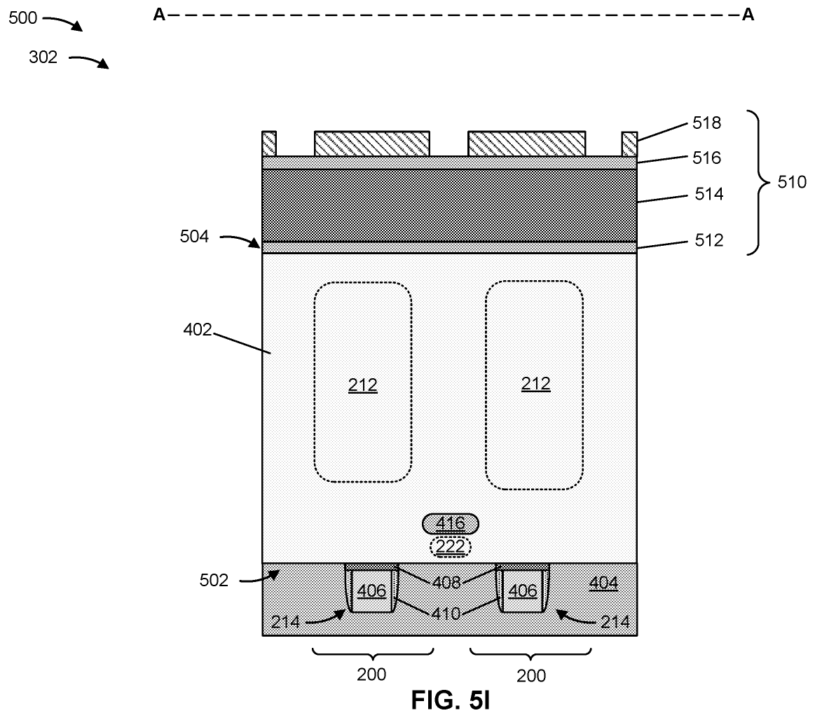

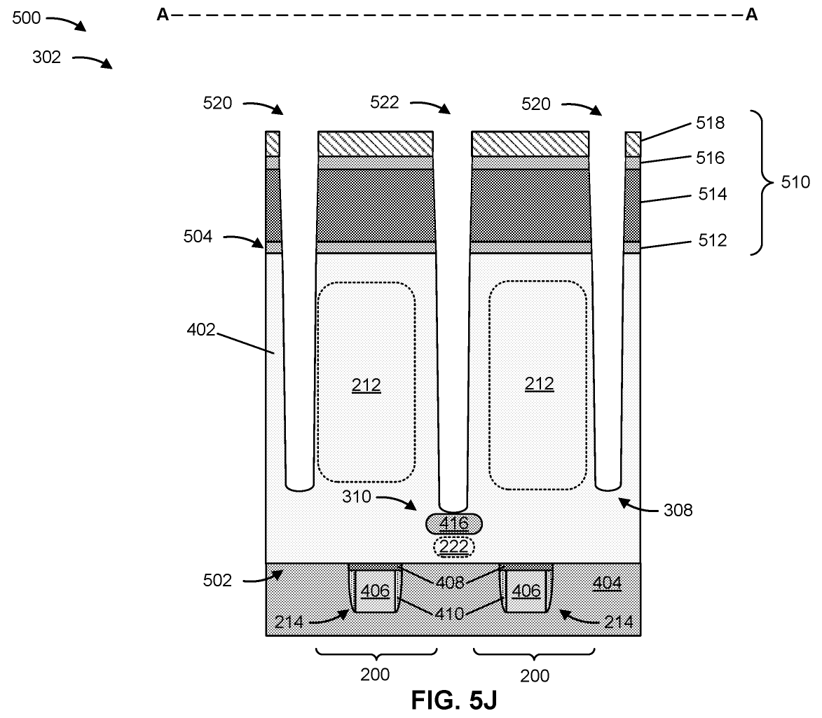

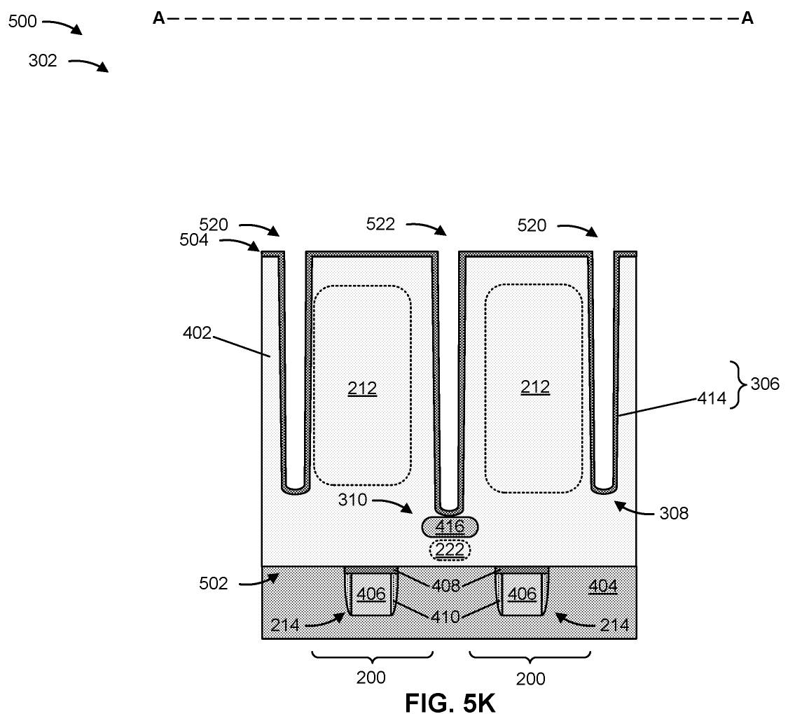

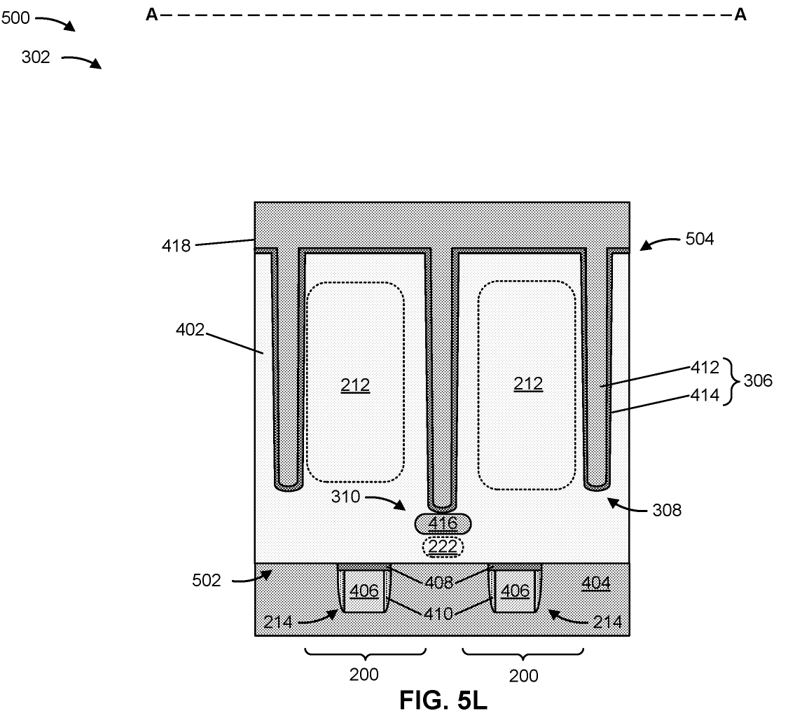

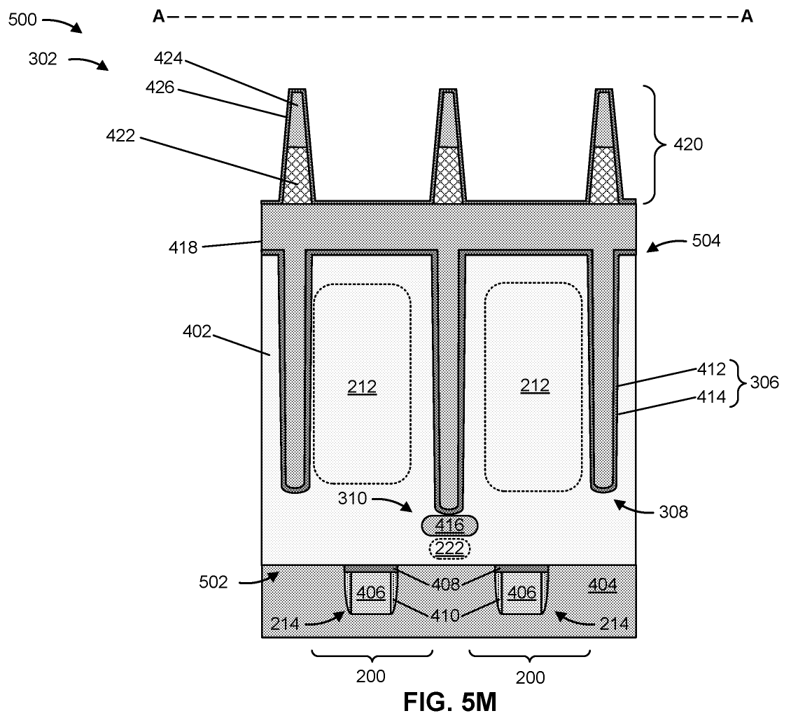

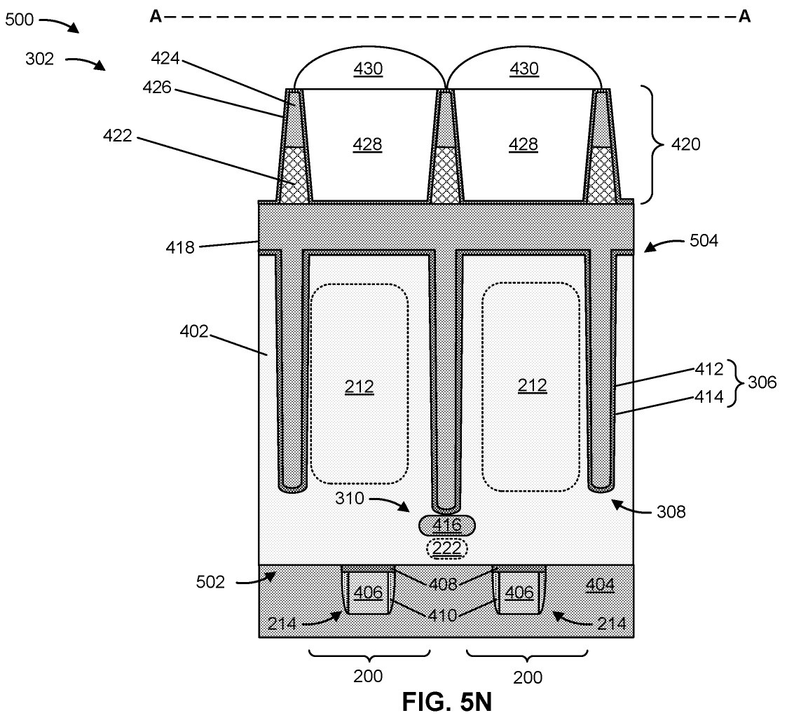

In some implementations, one or more of the semiconductor processing tools 102-114 and/or the wafer/die transport tool 116 may be used to perform other semiconductor processing operations described herein, such as in connection with FIGS. 5A-5N, 6A-6G, 8, and/or 9, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

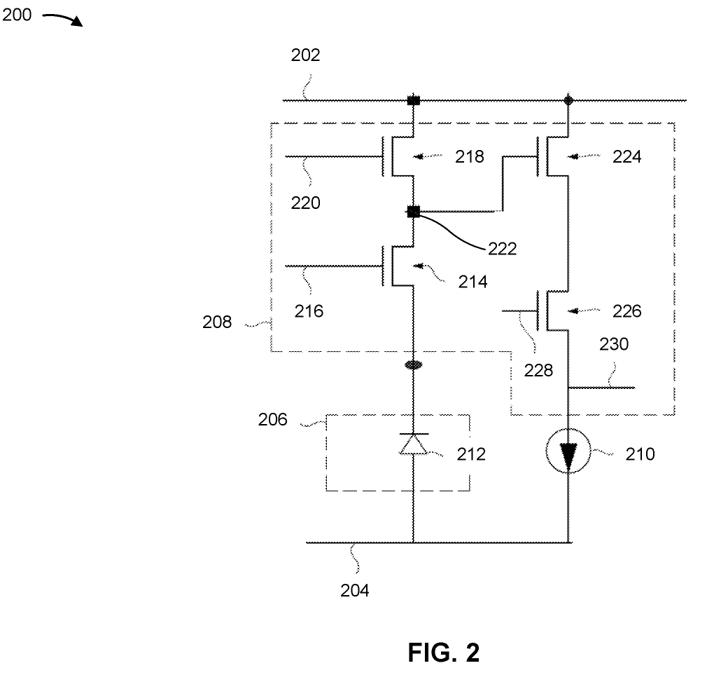

FIG. 2 is a diagram of an example of a pixel sensor 200 described herein. The pixel sensor 200 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 200 may be electrically connected to a supply voltage (V_{dd}) 202 and an electrical ground 204.

The pixel sensor 200 includes a sensing region 206 that may be configured to sense and/or accumulate incident light (e.g., light directed toward the pixel sensor 200). The pixel sensor 200 also includes a control circuitry region 208. The control circuitry region 208 is electrically connected with the sensing region 206 and is configured to receive a photocurrent 210 that is generated by the sensing region 206. Moreover, the control circuitry region 208 is configured to transfer the photocurrent 210 from the sensing region 206 to downstream circuits such as amplifiers or analog-to-digital (AD) converters, among other examples.

The sensing region 206 includes a photodiode 212. The photodiode 212 may absorb and accumulate photons of the incident light, and may generate the photocurrent 210 based on absorbed photons. The magnitude of the photocurrent 210 is based on the amount of light collected in the photodiode 212. Thus, the accumulation of photons in the photodiode 212 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 212 is electrically connected with a source of a transfer gate 214 in the control circuitry region 208. The transfer gate 214 is configured to control the transfer of the photocurrent 210 from the photodiode 212. The photocurrent 210 is provided from the source of the transfer gate 214 to a drain of the transfer gate 214 based on selectively switching a gate of the transfer gate 214. The gate of the transfer gate 214 may be selectively switched by applying a transfer voltage (Vₜₓ) 216 to the transfer gate 214. In some implementations, the transfer voltage 216 being applied to the transfer gate 214 causes a conductive channel to form between the source and the drain of the transfer gate 214, which enables the photocurrent 210 to traverse along the conductive channel from the source to the drain. In some implementations, the transfer voltage 216 being removed from the transfer gate 214 (or the absence of the transfer voltage 216) causes the conductive channel to be removed such that the photocurrent 210 cannot pass from the source to the drain.

The control circuitry region 208 further includes a reset gate 218. The reset gate 218 is electrically connected to the supply voltage 202. The reset gate 218 may be controlled by a reset voltage (Vᵣₛₜ) 220. The transfer gate 214 and the reset gate 218 may be electrically coupled with a floating diffusion node 222. The reset voltage 220 may be applied to the reset gate 218 to pull the drain of the transfer gate 214 to a high voltage (e.g., to the supply voltage 202) to “reset” the floating diffusion node 222 (e.g., by draining any residual charge in the floating diffusion node 222) prior to activation of the transfer gate 214 to transfer the photocurrent 210 from the photodiode 212 to the floating diffusion node 222.

The photocurrent 210 may be used to apply a floating diffusion voltage (V_{fd}) to a source follower gate 224 of the control circuitry region 208. This permits the photocurrent 210 to be observed without removing or discharging the photocurrent 210 from the floating diffusion node 222. The reset gate 218 may instead be used to remove or discharge the photocurrent 210 from the floating diffusion node 222.

The source follower gate 224 functions as a high impedance amplifier for the pixel sensor 200. The source follower gate 224 provides a voltage to current conversion of the floating diffusion voltage. The output of the source follower gate 224 is electrically connected with a row select gate 226, which is configured to control the flow of the photocurrent 210 to external circuitry. The row select gate 226 is controlled by selectively applying a select voltage (V_{di}) 228 to the gate of the row select gate 226. This permits the photocurrent 210 to flow to an output 230 of the pixel sensor 200.

As indicated above, FIG. 2 is provided as an example. Other examples may differ from what is described with regard to FIG. 2.

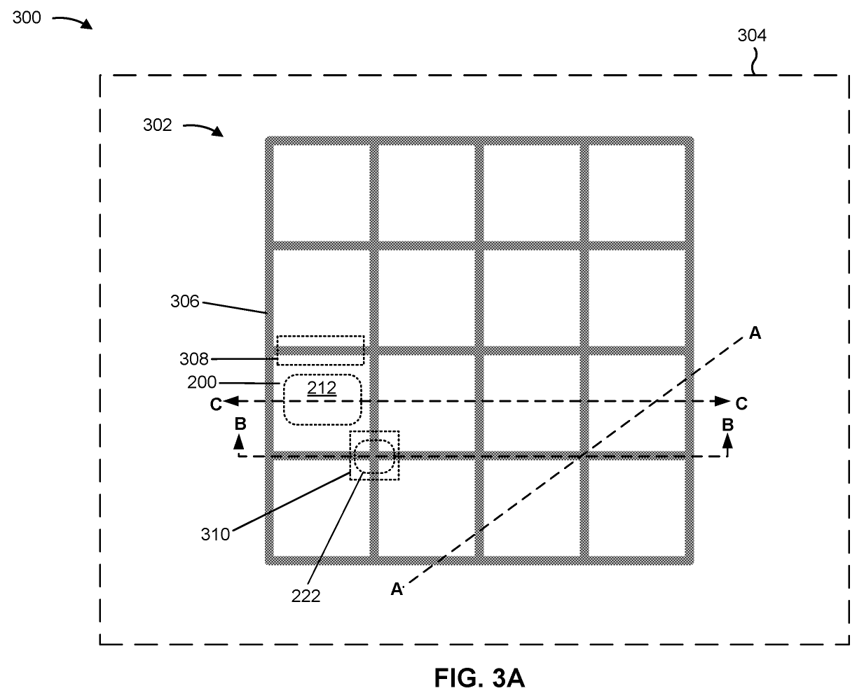

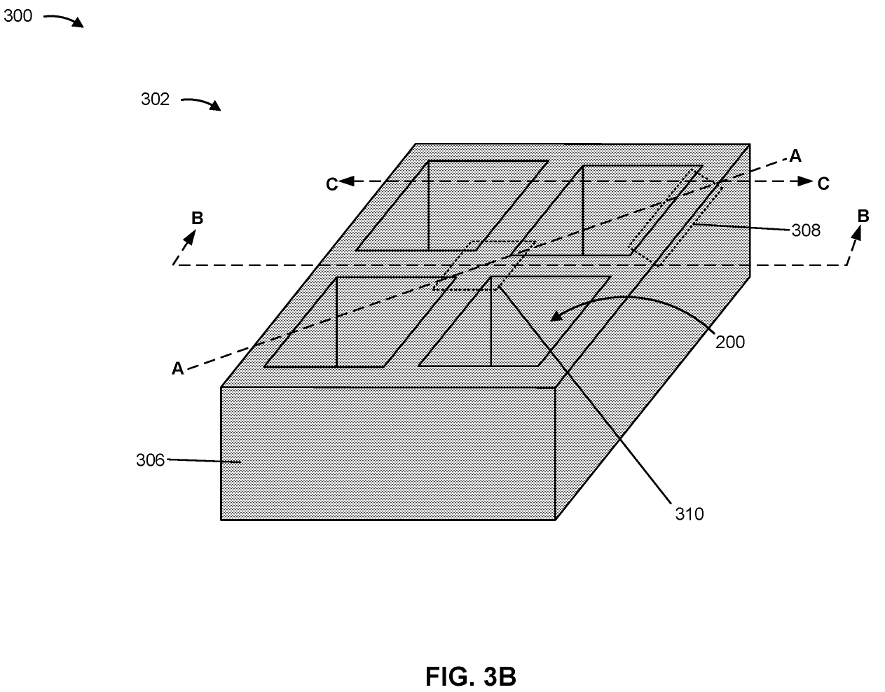

FIGS. 3A and 3B are diagrams of an example implementation 300 of a pixel sensor array 302 described herein. FIG. 3A illustrates a top-down view of the pixel sensor array 302 and FIG. 3B illustrates a perspective view of the pixel sensor array 302. In some implementations, the pixel sensor array 302 may be included in an image sensor 304. The image sensor 304 may include a CMOS image sensor (CIS), a backside illuminated (BSI) CMOS image sensor, a front side illuminated (FSI) CMOS image sensor, or another type of image sensor.

As shown in FIGS. 3A and 3B, the pixel sensor array 302 may include a plurality of pixel sensors 200. As further shown in FIGS. 3A and 3B, the pixel sensors 200 may be arranged in a grid. In some implementations, the pixel sensors 200 are square-shaped (as shown in the example in FIGS. 3A and 3B). In some implementations, the pixel sensors 200 include other shapes such as rectangle shapes, circle shapes, octagon shapes, diamond shapes, and/or other shapes.

The pixel sensors 200 may be configured to sense and/or accumulate incident light (e.g., light directed toward the pixel sensor array 302). For example, a pixel sensor 200 may absorb and accumulate photons of the incident light in a photodiode 212. The accumulation of photons in the photodiode 212 may generate a charge (e.g., a photocurrent) representing the intensity or brightness of the incident light (e.g., a greater amount of charge may correspond to a greater intensity or brightness, and a lower amount of charge may correspond to a lower intensity or brightness). The photocurrent may be transferred to a floating diffusion node 222 for storage, for amplification, and/or for transfer to another node. In some implementations, at least a subset of the pixel sensors 200 may be configured to sense incident light in the visible light wavelength spectrum. In some implementations, at least a subset of the pixel sensors 200 may be configured to sense incident light in the infrared light or near infrared light wavelength spectrum.

In some implementations, the size of the pixel sensors 200 (e.g., the width or the diameter) of the pixel sensors 200 is less than approximately 1 micron. In these examples, the pixel sensors 200 may be referred to as sub-micron pixel sensors. Sub-micron pixel sensors may decrease the pixel sensor pitch (e.g., the distance between adjacent pixel sensors) in the pixel sensor array 302, which may enable increased pixel sensor density in the pixel sensor array 302 (which can increase the performance of the pixel sensor array 302).

As shown in FIGS. 3A and 3B, the pixel sensors 200 may be electrically and optically isolated by a BDTI structure 306 included in the pixel sensor array 302. The BDTI structure 306 may include a plurality of interconnected and intersecting trenches that are filled with one or more types of materials, such as a dielectric material (e.g., an oxide-containing material, a high dielectric constant (high-k) dielectric material), a polysilicon material, and/or another type of material. The trenches of the BDTI structure 306 may be included around the perimeters of the pixel sensors 200 such that the BDTI structure 306 surrounds the photodiodes 212 of the pixel sensors 200, as shown in FIG. 3A.

As further shown in FIGS. 3A and 3B, portions of the BDTI structure 306 extend along a side of one or two pixel sensors 200. These portions of the BDTI structure 306 are referred to as non-cross-road portions (or non-X-road portions) 308 of the BDTI structure 306. Portions of the BDTI structure 306 that intersect at corners of three or more pixel sensors 200 are referred to as cross-road portions (or X-road portions) 310 of the BDTI structure 306.

As shown in FIG. 3A, a floating diffusion node 222 of a pixel sensor 200 may be included between corners of a plurality of pixel sensors 200 in a cross-road portion of the BDTI structure 306. In particular, the floating diffusion node 222 is included under the cross-road portion of the BDTI structure 306. Including the floating diffusion node 222 under the BDTI structure 306 (e.g., in the cross-road portion 310) provides more area within the perimeter of the BDTI structure 306 for the photodiode 212 of the pixel sensor 200, which enables the photodiode 212 to be larger than if the floating diffusion node 222 were also included within the perimeter of the BDTI structure 306. This provides greater quantum efficiency and greater light sensitivity for the pixel sensor 200. Alternatively, for the same size photodiode 212, the area of the pixel sensor 200 may be smaller, thereby enabling a greater density of pixel sensors 200 to be included in the pixel sensor array 302.

The BDTI structure 306 may extend into (and may be included in) a substrate (not shown) in which the pixel sensors 200 are formed to surround the photodiodes 212 and other structures of the pixel sensors 200 in the substrate. As indicated above, the pixel sensor array 302 may be included in a BSI CMOS image sensor. In these examples, the BDTI structure 306 may be formed from the backside of substrate of the pixel sensor array 302.

FIGS. 3A and 3B further illustrate a reference cross-section A-A and a reference cross-section B-B that are used in one or more figures described herein. Cross-section A-A is in a plane across a plurality of pixel sensors 200 of the pixel sensor array 302. The plane extends across one or more non-cross-road portions 308 and one or more cross-road portions 310 of the BDTI structure 306. Subsequent figures refer to this reference cross-section for clarity. Cross-section B-B is in a plane across the BDTI structure 306, and includes one or more non-cross-road portions 308 and one or more cross-road portions 310 of the BDTI structure 306. The cross-section B-B is used in subsequent figures to illustrate an elevation view in which a cross-section C-C is superimposed in background with the cross-section B-B in the foreground. In some figures, some reference numbers of components or features illustrated therein may be omitted to avoid obscuring other components or features for ease of depicting the figures.

As indicated above, FIGS. 3A and 3B are provided as an example. Other examples may differ from what is described with regard to FIGS. 3A and 3B.

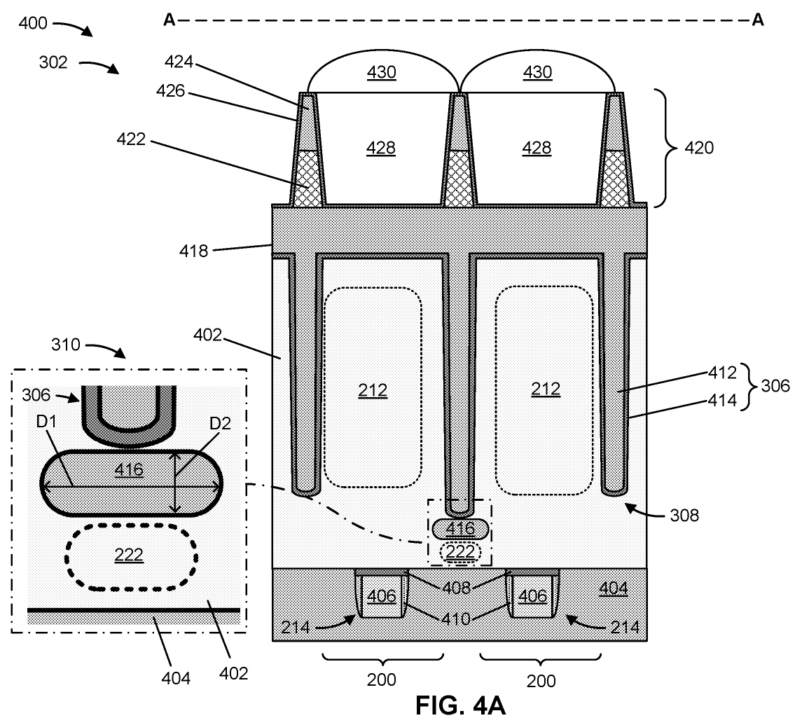

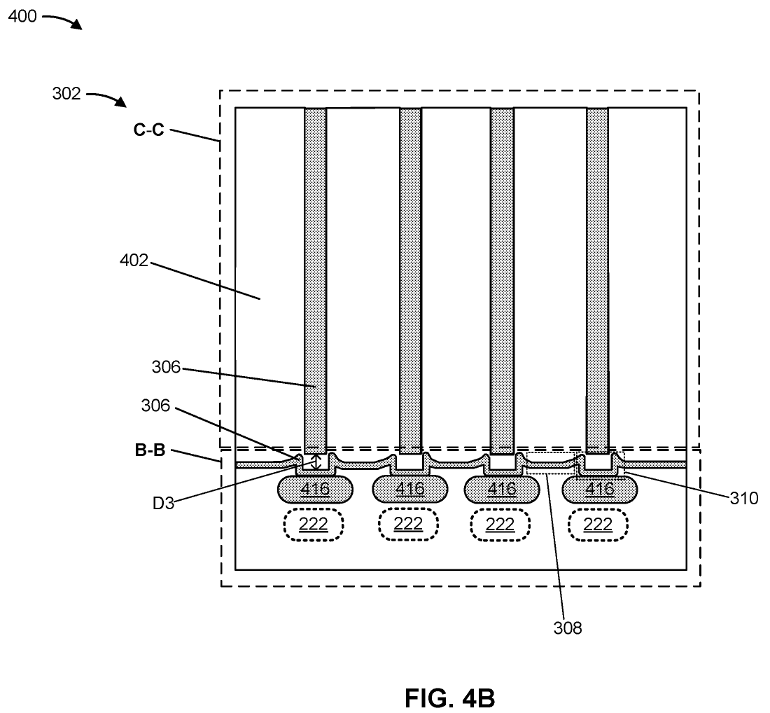

FIGS. 4A and 4B are diagrams of an example implementation 400 of a portion of the pixel sensor array 302 described herein. FIG. 4A illustrates a cross-sectional view of the cross-section A-A of the portion of the pixel sensor array 302. FIG. 4B illustrates an elevation view of the portion of the pixel sensor array 302 in which the cross-section C-C is superimposed in background the figures with the cross-section B-B in the foreground.

As shown in FIG. 4A, the pixel sensors 200 of the pixel sensor array 302 may be formed in and/or on a semiconductor layer 402, which may be the substrate of the pixel sensor array 302. The semiconductor layer 402 may include a silicon (Si) substrate, a substrate formed of a material including silicon, a III-V compound semiconductor material substrate such as gallium arsenide (GaAs), a germanium (Ge) substrate, a silicon germanium (SiGe) substrate, or another type of semiconductor substrate.

The pixel sensors 200 may each include a photodiode 212 in the semiconductor layer 402. The photodiodes 212 between sections of the BDTI structure 306 such that the photodiodes 212 are optically isolated from one another. The photodiodes 212 may each include one or more of regions of the semiconductor layer 402 that are doped with various types of ions to form a p-n junction or a PIN junction (e.g., a junction between a p-type portion, an intrinsic (or undoped) type portion, and an n-type portion). For example, the semiconductor layer 402 may be doped with an n-type dopant to form one or more n-type regions of a photodiode 212, and the semiconductor layer 402 may be doped with a p-type dopant to form a p-type region of the photodiode 212. A photodiode 212 may be configured to absorb photons of incident light (e.g., visible light, near infrared light). The absorption of photons causes the photodiode 212 to accumulate a charge (referred to as a photocurrent 210) due to the photoelectric effect. Photons may bombard the photodiode 212, which causes emission of electrons and holes in the photodiode 212, which causes the photocurrent 210 to be generated.

A floating diffusion node 222 may be included in a cross-road portion 310 at the corners of a plurality of pixel sensors 200. In particular, the floating diffusion node 222 may be included under the cross-road portion 310 of the BDTI structure 306 between the BDTI structure 306 and a frontside surface of the semiconductor layer 402. The floating diffusion node 222 may include a highly-doped n-type region (e.g., an n⁺ doped region) of the semiconductor layer 402. In some implementations, a drain extension region is included in the semiconductor layer 402 adjacent to the floating diffusion node 222. The drain extension region may include lightly-doped n-type region(s) that facilitate the transfer of photocurrent 210 from the photodiode 212 to the floating diffusion node 222.

A pixel sensor 200 may include a transfer gate 214 on the frontside surface of the semiconductor layer 402. The transfer gate 214 may be configured to selectively control the transfer of the photocurrent 210 from a photodiode 212 of the pixel sensor 200 to the floating diffusion node 222 by selectively controlling the conductivity of the semiconductor layer 402 between the photodiode 212 and the floating diffusion node 222. The transfer gates 214 of the pixel sensors 200 may be included in a dielectric layer 404 that is included on the frontside surface of the semiconductor layer 402. The dielectric layer 404 may include a dielectric material such as a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

A transfer gate 214 may include a gate electrode 406 and a gate dielectric layer 408 between the gate electrode 406 and the semiconductor layer 402. In some implementations, the gate electrode 406 includes polysilicon. In some implementations, the gate electrode 406 includes one or more metals, such as tungsten (W), cobalt (Co), ruthenium (Ru), titanium (Ti), aluminum (Al), copper (Cu), gold (Au), aluminum (Al), an alloy thereof, among other examples of metals. The gate dielectric layer 408 may include a silicon nitride (SiₓN_{y}), a hafnium oxide (HfOₓ), another high-k dielectric material, a silicon oxide (SiOₓ), and/or another dielectric material.

Sidewall spacers 410 may be included on and/or around sidewalls of the gate electrodes 406. The sidewall spacers 410 may include one or more dielectric materials such as a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

As further shown in FIG. 4A, the BDTI structure 306 may extend into the semiconductor layer 402. In particular, the BDTI structure 306 may extend into the semiconductor layer 402 from a backside surface of the semiconductor layer 402 and toward the frontside surface of the semiconductor layer 402. The BDTI structure 306 is referred to as a backside DTI structure in that the BDTI structure 306 is formed into the semiconductor layer 402 from the backside surface of the semiconductor layer 402. The BDTI structure 306 may be formed from the backside of the semiconductor layer 402 as part of backside processing of the pixel sensor array 302. The backside of the semiconductor layer 402 may be the side of the semiconductor layer 402 opposing the front side on which the transfer gates 214 are included.

The BDTI structure 306 may include elongated structures of dielectric material 412 and a dielectric liner 414 between the dielectric material 412 and the semiconductor layer 402. The dielectric liner 414 may be included on sidewalls and on a bottom surface of the BDTI structure 306, and may be included as an antireflective coating (ARC) and/or to further facilitate electrical and/or optical isolation of the pixel sensors 200. In some implementations, the dielectric material 412 includes a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. In some implementations, the dielectric liner 414 may include a high-k dielectric material such as a silicon nitride (SiₓN_{y}), a hafnium oxide (HfOₓ), and/or another high-k dielectric material.

As further shown in FIG. 4A, dielectric etch stop structures 416 are included under the cross-road portions 310 of the BDTI structure 306 such that a dielectric etch stop structure 416 is located between a floating diffusion node 222 and a cross-road portion 310 of the BDTI structure 306. A dielectric etch stop structure 416 is embedded in the semiconductor layer 402 between a floating diffusion node 222 and a cross-road portion 310 of the BDTI structure 306 to prevent or reduce the likelihood of etching into the floating diffusion node 222 when etching the semiconductor layer 402 to form trenches in which the BDTI structure 306 is to be formed. In particular, the dielectric etch stop structure 416 is included between a floating diffusion node 222 and a cross-road portion 310 of the BDTI structure 306 so that the etching of the trenches, in which the BDTI structure 306 is to be formed, stops on the dielectric etch stop structure 416 in the cross-road portion 310, as opposed to etching into the underlying floating diffusion node 222 due to etch depth loading. In some implementations, the etching of the trenches, in which the BDTI structure 306 is to be formed, consumes a portion of the dielectric etch stop structure 416 (e.g., without the etching punching through the dielectric etch stop structure 416). In these implementations, the bottom of the BDTI structure 306 in the cross-road portion 310 may extend into a portion of the dielectric etch stop structure 416.

The dielectric etch stop structures 416 include one or more dielectric materials, such as a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The material(s) of the dielectric etch stop structures 416 are selected to have etch selectivity, relative to the semiconductor layer 402, for the etchants that are used to etch the semiconductor layer 402 to form the trenches. For example, an etchant that has a high etch rate for silicon (Si) may be used to etch the semiconductor layer 402 to form the trenches. Thus, the material(s) of the dielectric etch stop structures 416 may be selected such that the etchants that are used to etch the semiconductor layer 402 have a low etch rate for the dielectric etch stop structures 416.

As further shown in FIG. 4A, a dielectric etch stop structure 416 may have a dimension D1 corresponding to a cross-sectional width of the dielectric etch stop structure 416. The dielectric etch stop structure 416 is formed such that the cross-sectional width of the dielectric etch stop structure 416 results in the cross-road portion 310 of the BDTI structure 306 being fully within a perimeter of the dielectric etch stop structure 416. This ensures that the dielectric etch stop structure 416 is physically large enough to fully contain the etching of the trenches of the BDTI structure 306 in the cross-road portion 310 to minimize and/or prevent etching of the trenches of the BDTI structure 306 below the dielectric etch stop structure 416 and into the underlying floating diffusion node 222. The dielectric etch stop structure 416 is formed such that the cross-sectional width of the dielectric etch stop structure 416 results in the floating diffusion node 222 being fully within a perimeter of the dielectric etch stop structure 416 for similar purposes.

In some implementations, the cross-sectional width of the dielectric etch stop structure 416 (e.g., the dimension D1) is included in a range of approximately 200 nanometers to approximately 250 nanometers. If the cross-sectional width is less than approximately 200 nanometers, the dielectric etch stop structure 416 may not provide sufficient etching protection to prevent etching into the floating diffusion node 222. If the cross-sectional width is greater than approximately 250 nanometers, the dielectric etch stop structure 416 may block some of the photocurrent 210 from being transferred from the photodiodes 212 to the floating diffusion node 222, which may reduce the efficiency and light sensitivity of the pixel sensors 200. If the cross-sectional width is included in the range of approximately 200 nanometers to approximately 250 nanometers, the dielectric etch stop structure 416 may provide sufficient etching protection while enabling a high efficiency and light sensitivity to be achieved for the pixel sensors 200. However, other values for the cross-sectional width, and ranges other than approximately 200 nanometers to approximately 250 nanometers, are within the scope of the present disclosure.

As further shown in FIG. 4A, a dielectric etch stop structure 416 may have another dimension D2 corresponding to a thickness of the dielectric etch stop structure 416. In some implementations, the thickness of the dielectric etch stop structure 416 is included in a range of approximately 50 nanometers to approximately 200 nanometers. If the thickness is less than approximately 50 nanometers, the dielectric etch stop structure 416 may not provide sufficient etching protection to prevent etching into the floating diffusion node 222. If the thickness is greater than approximately 200 nanometers, the dielectric etch stop structure 416 may block some of the photocurrent 210 from being transferred from the photodiodes 212 to the floating diffusion node 222, which may reduce the efficiency and light sensitivity of the pixel sensors 200. If the thickness is included in the range of approximately 50 nanometers to approximately 200 nanometers, the dielectric etch stop structure 416 may provide sufficient etching protection while enabling a high efficiency and light sensitivity to be achieved for the pixel sensors 200. However, other values for the thickness, and ranges other than approximately 200 nanometers to approximately 250 nanometers, are within the scope of the present disclosure.

As further shown in FIG. 4A, a buffer layer 418 may be included over the backside of the semiconductor layer 402. The buffer layer 418 may include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

A composite metal grid 420 is included above the buffer layer 418. The composite metal grid 420 includes a grid of intersecting columns that substantially conforms to the shape of the grid of the BDTI structure 306. The composite metal grid 420 may include a layer stack of a dielectric portion 424 and a metal portion 422. Alternatively, a metal grid with only a metal portion 422 may be included above the buffer layer 418. A liner 426 may be included over the composite metal grid 420.

The metal portion 422 may include one or more metals, such as tungsten (W), cobalt (Co), ruthenium (Ru), titanium (Ti), aluminum (Al), copper (Cu), gold (Au), aluminum (Al), an alloy thereof, among other examples of metals. The dielectric portions 424 may include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The liner 426 may include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

As further shown in FIG. 4, color filters 428 may be recessed in the composite metal grid 420 and may be included between the columns of the composite metal grid 420. In some implementations, the color filters 428 include visible light color filters configured to filter a particular wavelength or a particular wavelength range of visible light (e.g., red light, blue light, or green light). In some implementations, at least a subset of the color filters 428 includes a near infrared (NIR) filter (e.g., an NIR bandpass filter) configured to permit wavelengths associated with NIR light to pass through the color filters 428 and to block other wavelengths of light. In some implementations, at least a subset of the color filters 428 includes an NIR cut filter configured to block NIR light from passing through the color filters 428. In some implementations, color filters 428 may be omitted from one or more pixel sensors 200 to permit all wavelengths of light to pass through to the associated photodiodes 212. In these examples, the pixel sensor(s) 200 may be configured as a white pixel sensor(s).

Micro-lenses 430 may be included above and/or on the color filters 428. The micro-lenses 430 may include micro-lenses for the pixel sensors 200 configured to focus incident light toward the photodiodes 212 and/or to reduce optical crosstalk between the pixel sensors 200.

As shown in FIG. 4B, the depth to which the BDTI structure 306 extends in the semiconductor layer 402 may be greater in the cross-road portions 310 than in the non-cross-road portions 308. However, the inclusion of the dielectric etch stop structures 416 under the cross-road portions 310 of the BDTI structure 306 reduces a difference in depth of the cross-road portions 310 and the non-cross-road portions 308 (corresponding to dimension D3 in FIG. 4B) than if no dielectric etch stop structures 416 were included. The reduced difference in depth results in minimal to no etching into the underlying floating diffusion nodes 222.

As indicated above, FIGS. 4A and 4B are provided as an example. Other examples may differ from what is described with regard to FIGS. 4A and 4B.

FIGS. 5A-5N are diagrams of an example implementation 500 of forming the pixel sensor array 302 of the image sensor device 304 described herein. FIGS. 5A-5N illustrate cross-section views of the example implementation 500 along the cross-section A-A of the pixel sensor array 302 in FIG. 4A. In some implementations, one or more processing operations described in connection with FIGS. 5A-5N may be performed using one or more of the semiconductor processing tools 102-114 illustrated and described in connection with FIG. 1. In some implementations, one or more processing operations described in connection with FIGS. 5A-5N may be performed using another semiconductor processing tool.

Turning to FIG. 5A, the example implementation 500 of forming the pixel sensor array 302 may be performed in connection with the semiconductor layer 402. The semiconductor layer 402 may be provided as a semiconductor wafer or another type of semiconductor work piece. One or more processing operations described in connection with FIGS. 5A-5N may be performed from a frontside surface 502 of the semiconductor layer 402, and one or more other processing operations described in connection with FIGS. 5A-5N may be performed from a backside surface 504 of the semiconductor layer 402. The backside surface 504 may be a surface of the semiconductor layer 402 opposing the frontside surface 502.

As shown in FIG. 5B, a plurality of regions of the semiconductor layer 402 may be doped to form photodiodes 212 for one or more pixel sensors 200. For example, an ion implantation tool 114 may be used to dope the semiconductor layer 402 to form one or more n-type regions and/or one or more p-type regions of the photodiodes 212. The ion implantation tool 114 may be used to implant p⁺ ions in the semiconductor layer 402 through the frontside surface 502 to form the p-type region(s) and/or may be used to implant n⁺ ions in the semiconductor layer 402 to form the n-type region(s).

As shown in FIG. 5C, a masking layer 506 may be formed on the frontside surface 502 of the semiconductor layer 402. A deposition tool 102 may be used to deposit the masking layer 506 using a PVD technique, an ALD technique, a CVD technique, a spin-coating technique, an oxidation technique, another type of deposition technique described in connection with FIG. 1, and/or another suitable deposition technique. The masking layer 506 may be deposited in one or more deposition operations. The masking layer 506 may include a photoresist, a hard mask, and/or another type of masking layer.

As further shown in FIG. 5C, a pattern may be formed in the masking layer 506. The pattern may be formed by removing portions of the masking layer 506 to expose portions of the frontside surface 502 of the semiconductor layer 402. An exposure tool 104 may be used to expose the masking layer 506 to a radiation source to pattern the masking layer 506. A developer tool 106 may be used to develop and remove portions of the masking layer 506 to expose the pattern. Additionally and/or alternatively, the pattern may be formed in a photoresist layer, and the pattern may be transferred to the masking layer 506 by etching the masking layer 506 (e.g., using an etch tool 108) based on the pattern in the photoresist layer.

As shown in FIG. 5D, one or more ion implantation operations may be performed to form a plurality of implant regions 508 in the semiconductor layer 402 from the frontside surface 502. An ion implantation operations may be performed to implant ions in the semiconductor layer 402 to form the implant regions 508 based on the pattern in the masking layer 506. Thus, the masking layer 506 functions as an implant mask in the one or more ion implantation operations. In some implementations, the ions include oxygen ions, and the oxygen ions are implanted to form an oxide of the semiconductor material of the semiconductor layer 402. The implantation of the oxygen ions oxygenates the material of the semiconductor layer 402 to form the implant regions 508. For example, the oxygen ions may form silicon dioxide (SiO₂) from the silicon (Si) material of the semiconductor layer 402. In some implementations, the ions include nitrogen ions, and the nitrogen ions are implanted to form a nitride of the semiconductor material of the semiconductor layer 402. The implantation of the nitrogen ions nitrogenizes the material of the semiconductor layer 402 to form the implant regions 508. For example, the nitrogen ions may form silicon nitride (Si₃N₄) from the silicon (Si) material of the semiconductor layer 402.

As shown in FIG. 5E, a thermal operation may be performed to anneal the implant regions 508 to form a dielectric etch stop structure 416 from the implant regions 508. The thermal operation may include increasing the temperature of the semiconductor layer 402 for a time duration to cause the material of the implant regions 508 to diffuse and merge into a singular structure corresponding to the dielectric etch stop structure 416.

As further shown in FIG. 5E, the dielectric etch stop structure 416 may be formed a distance (corresponding to a dimension D4) below the frontside surface 502 of the semiconductor layer 402 and a distance (corresponding to a dimensionD5) from the backside surface 504 of the semiconductor layer 402. The distance below the frontside surface 502 (the dimension D4) may be included in a range of approximately 200 nanometers to approximately 1000 nanometers. If the distance below the frontside surface 502 is less than approximately 200 nanometers, insufficient space may be provided for forming a floating diffusion node 222 between the dielectric etch stop structure 416 and the frontside surface 502 of the semiconductor layer 402. If the distance below the frontside surface 502 is greater than approximately 1000 nanometers, insufficient space may be provided for forming a BDTI structure 306 between the dielectric etch stop structure 416 and the backside surface 504 of the semiconductor layer 402. If the distance below the frontside surface 502 is included in the range of approximately 200 nanometers to approximately 1000 nanometers, sufficient area may be provided in the semiconductor layer 402 for formation of the floating diffusion node 222 and the BDTI structure 306. However, other values for the distance below the frontside surface 502, and ranges other than approximately 200 nanometers to approximately 1000 nanometers, are within the scope of the present disclosure.

The distance above the backside surface 504 (the dimension D5) may be greater than approximately 2400 nanometers. If the distance above the backside surface 504 is less than approximately 2400 nanometers, insufficient space may be provided for forming a BDTI structure 306 between the dielectric etch stop structure 416 and the backside surface 504 of the semiconductor layer 402. However, other values for the distance above the backside surface 504 are within the scope of the present disclosure.

As shown in FIG. 5F, one or more regions of the semiconductor layer 402 above the dielectric etch stop structures 416 may be doped to form floating diffusion nodes 222 of the one or more pixel sensors 200. In some implementations, an ion implantation tool 114 may be used to dope by implanting n⁺ ions in the semiconductor layer 402 to form the floating diffusion nodes 222. The floating diffusion nodes 222 may be formed from the frontside surface 502 of the semiconductor layer 402. A distance between the frontside surface 502 of the semiconductor layer 402 and a floating diffusion node 222 (corresponding to dimension D6 in FIG. 5F) is less than the distance between the frontside surface 502 of the semiconductor layer 402 and a dielectric etch stop structure 416 (corresponding to dimension D4 in FIG. 5F). A distance between the frontside surface 502 of the semiconductor layer 402 and a floating diffusion node 222 (corresponding to dimension D6 in FIG. 5F) may also less than the distance between the frontside surface 502 of the semiconductor layer 402 and a photodiode 212 (corresponding to dimension D7 in FIG. 5F).

As shown in FIG. 5G, gate dielectric layers 408 of transfer gates 214 of the pixel sensors 200 may be formed over and/or on the frontside surface 502 of the semiconductor layer 402. Moreover, gate electrodes 406 of the transfer gates 214 may be formed over and/or on the gate dielectric layers 408. A deposition tool 102 may be used to deposit the gate dielectric layers 408 in a PVD operation, an ALD operation, a CVD operation, an oxidation operation, or another type of deposition operation. In some implementations, a planarization tool 110 may be used to planarize the gate dielectric layers 408 after the gate dielectric layers 408 are deposited. A deposition tool 102 and/or a plating tool 112 may be used to deposit the gate electrodes 406 using a CVD technique, a PVD technique, an ALD technique, an electroplating technique, another deposition technique described above in connection with FIG. 1, and/or another suitable deposition technique.

As further shown in FIG. 5G, sidewall spacers 410 may be formed on sidewalls of the gate electrodes 406. A deposition tool 102 may be used to deposit the sidewall spacers 410 in a PVD operation, an ALD operation, a CVD operation, an oxidation operation, and/or another type of deposition operation. In some implementations, a conformal layer of dielectric material is deposited, and then an etch tool 108 is used to remove portions of the dielectric layer, where the remaining portions of the dielectric layer correspond to the sidewall spacers 410. Accordingly, the sidewall spacers 410 may have a rounded outer surface resulting from the etch operation.

As shown in FIG. 5H, a dielectric layer 404 may be deposited on the frontside surface 502 of the semiconductor layer 402 and over the transfer gates 214. A deposition tool 102 may be used to deposit the dielectric layer 404 using a PVD technique, an ALD technique, a CVD technique, an oxidation technique, another type of deposition technique described in connection with FIG. 1, and/or another suitable deposition technique. The dielectric layer 404 may be deposited in one or more deposition operations. In some implementations, a planarization tool 110 may be used to planarize the dielectric layer 404 after the dielectric layer 404 is deposited.

FIGS. 5A-5H may correspond to frontside processing of the pixel sensor array 302 of the image sensor device 304. FIGS. 5I-5N may correspond to backside processing of the pixel sensor array 302 of the image sensor device 304.

As shown in FIG. 5I, a masking layer stack 510 is formed over and/or on the backside surface 504 of the semiconductor layer 402. The masking layer stack 510 may be used to form the trenches in which the BDTI structure 306 is to be formed. The masking layer stack 510 may include an antireflection layer 512, a bottom layer 514, a middle layer 516, and/or a photoresist layer 518, among other examples. The masking layer stack 510 may include the layers 512-518 to enable the trenches of the BDTI structure 306 to be formed to have a high or very high aspect ratio of a depth of the trenches to a width of the trenches.

A deposition tool 102 may be used to deposit the antireflection layer 512, a bottom layer 514, a middle layer 516, and/or a photoresist layer 518 using a PVD technique, an ALD technique, a CVD technique, a spin-coating technique, an oxidation technique, another type of deposition technique described in connection with FIG. 1, and/or another suitable deposition technique. The antireflection layer 512, a bottom layer 514, a middle layer 516, and/or a photoresist layer 518 may be deposited in one or more deposition operations. In some implementations, a planarization tool 110 may be used to planarize the antireflection layer 512, a bottom layer 514, a middle layer 516, and/or a photoresist layer 518 after the antireflection layer 512, a bottom layer 514, a middle layer 516, and/or a photoresist layer 518 are deposited.

As further shown in FIG. 5I, a pattern may be formed in the photoresist layer 518. The pattern may be formed by removing portions of the photoresist layer 518. An exposure tool 104 may be used to expose the photoresist layer 518 to a radiation source to pattern the photoresist layer 518. A developer tool 106 may be used to develop and remove portions of the photoresist layer 518 to expose the pattern. The pattern may be subsequently transferred to the antireflection layer 512, a bottom layer 514, and/or a middle layer 516.

As shown in FIG. 5J, an etch tool 108 may be used to etch the semiconductor layer 402 from the backside surface 504 of the semiconductor layer 402 to form trenches 520 and 522 in the semiconductor layer 402. The trenches 520 are formed in non-cross-road portions 308, and the trenches 522 are formed in cross-road portions 310. In the cross-road portions 310, etching of the trenches 522 stops on the dielectric etch stop structures 416. Thus, the dielectric etch stop structures 416 minimize and/or prevent the etching of the trenches 522 from extending into the underlying floating diffusion nodes 222. In some implementations, the etching of the trenches 522 extends into a portion of the dielectric etch stop structures 416.

The trenches 520 and 522 are formed based on the pattern formed in the masking layer stack 510. In some implementations, an etch technique is used to form the trenches 520 and 522 to have a high or very high aspect ratio of a depth of the trenches to a width of the trenches 520 and 522. For example, a deep reactive ion etch technique (sometimes referred to as a “Bosch” etch technique) may be used to form the trenches 520 and 522. This technique may involve the use of sequential operations to incrementally increase the depth of the trenches 520 and 522 in a highly controlled manner. The sequential operations may include a plurality of cycles of forming a protective film on the bottom surface and the sidewalls in the trenches 520 and 522, removing the protective film from the bottom surface, and increasing the depth of the trenches 520 and 522 as the protective film protects the sidewalls from being etched. This enables the depth of the trenches 520 and 522 to be increased with minimal increase to the width of the trenches 520 and 522. However, another etch technique may be used to form the trenches 520 and 522.

As shown in FIG. 5K, a dielectric liner 414 may be formed on sidewalls and on bottom surfaces of the trenches 520 and 522. In some implementations, portions of the dielectric liner 414 are also formed on the backside surface 504 of the semiconductor layer 402. A deposition tool 102 may be used to conformally deposit the dielectric liner 414 in a PVD operation, an ALD operation, a CVD operation, and/or another type of deposition operation. In some implementations, the dielectric liner 414 is subsequently removed from the backside surface 504 of the semiconductor layer 402. In some implementations, the dielectric liner 414 remains on the backside surface 504 of the semiconductor layer 402 (e.g., as an antireflective coating).

As shown in FIG. 5L, the trenches 520 and 522 may be filled with a dielectric material 412 (e.g., an oxide-containing dielectric material, a high-k dielectric material) over the dielectric liner 414 to form the BDTI structure 306 in the trenches 520 and 522. The BDTI structure 306 may be formed on the dielectric etch stop structures 416 in the cross-road portions 310. As further shown in FIG. 5L, the dielectric material 412 may be deposited over the backside surface 504 of the semiconductor layer 402 to form the buffer layer 418. A deposition tool 102 may be used to deposit the dielectric material 412 in the trenches 520 and 522 to form the BDTI structure 306 in a PVD operation, an ALD operation, a CVD operation, an oxidation operation, and/or another type of deposition operation. A deposition tool 102 may be used to deposit the buffer layer 418 in a PVD operation, an ALD operation, a CVD operation, an oxidation operation, and/or another type of deposition operation. In some implementations, a planarization tool 110 may be used to planarize the buffer layer 418 after the buffer layer 418 is deposited.

As shown in FIG. 5M, a composite metal grid 420 may be formed above the buffer layer 418. Forming the composite metal grid 420 may include depositing the layers of the composite metal grid 420 and using a pattern in a masking layer to etch the layers to form the metal portion 422 and/or the dielectric portion 424 of the composite metal grid 420. The liner 426 may then be conformally deposited on the metal portion 422 and/or on the dielectric portion 424.

As shown in FIG. 5N, color filters 428 may be formed in the composite metal grid 420 above the pixel sensors 200, and micro-lenses 430 may be formed over and/or on the color filters 428.

As indicated above, FIGS. 5A-5N are provided as an example. Other examples may differ from what is described with regard to FIGS. 5A-5N.

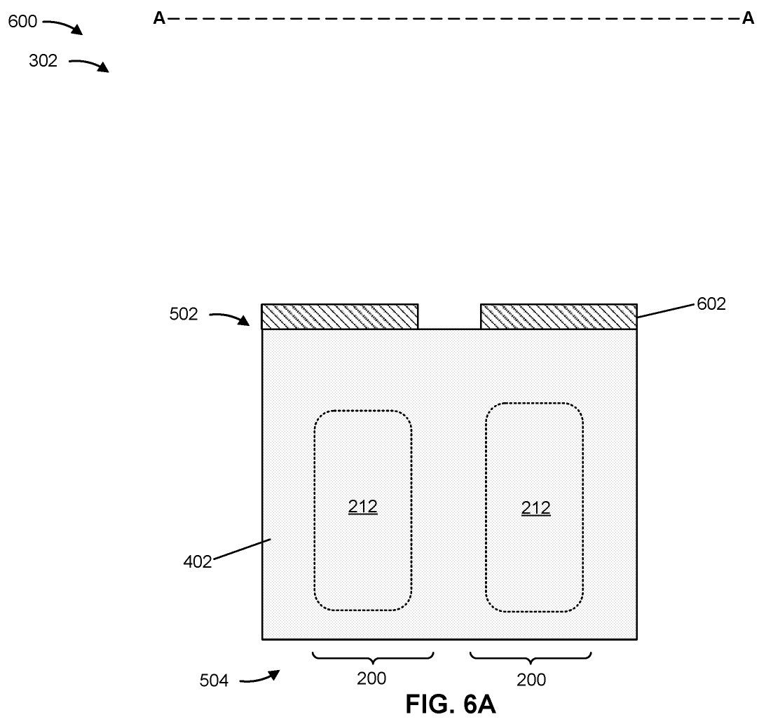

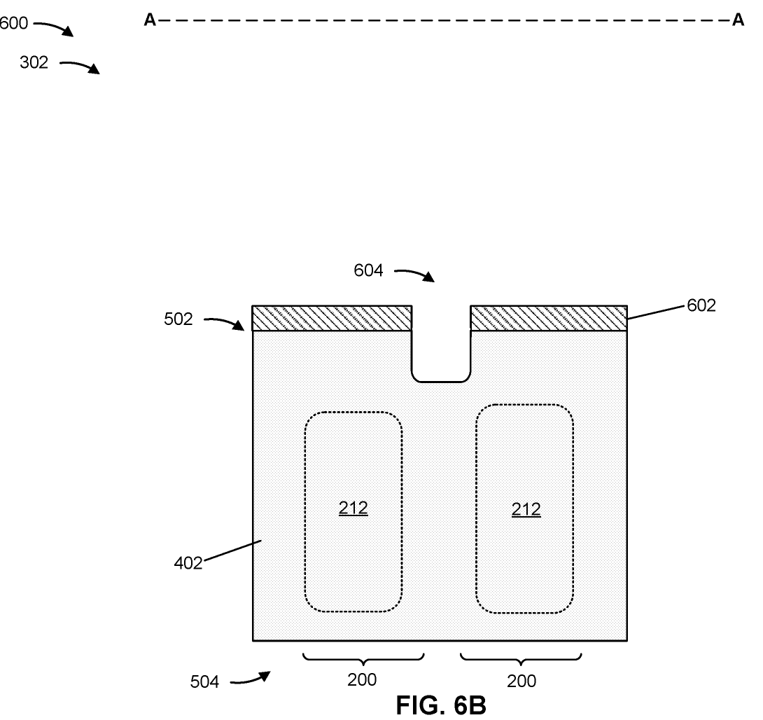

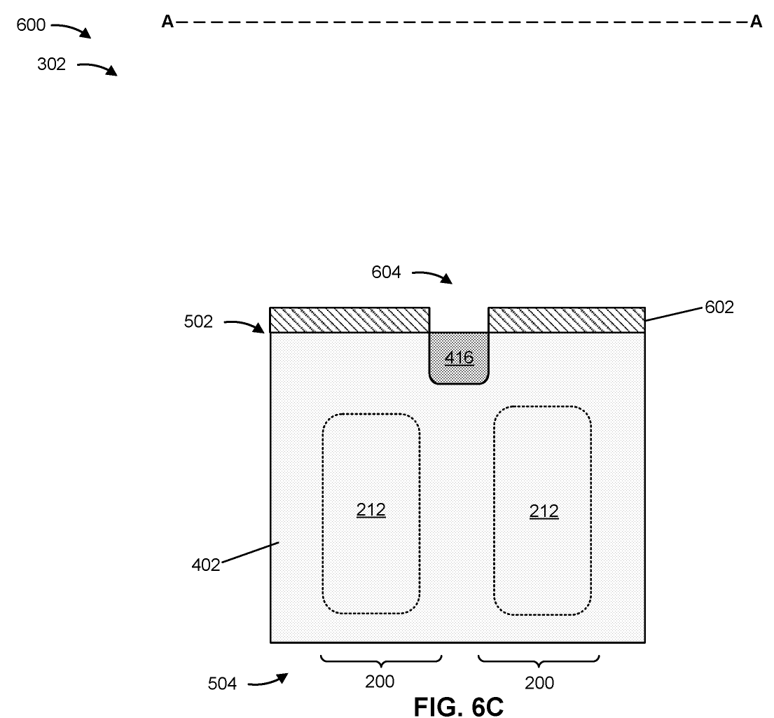

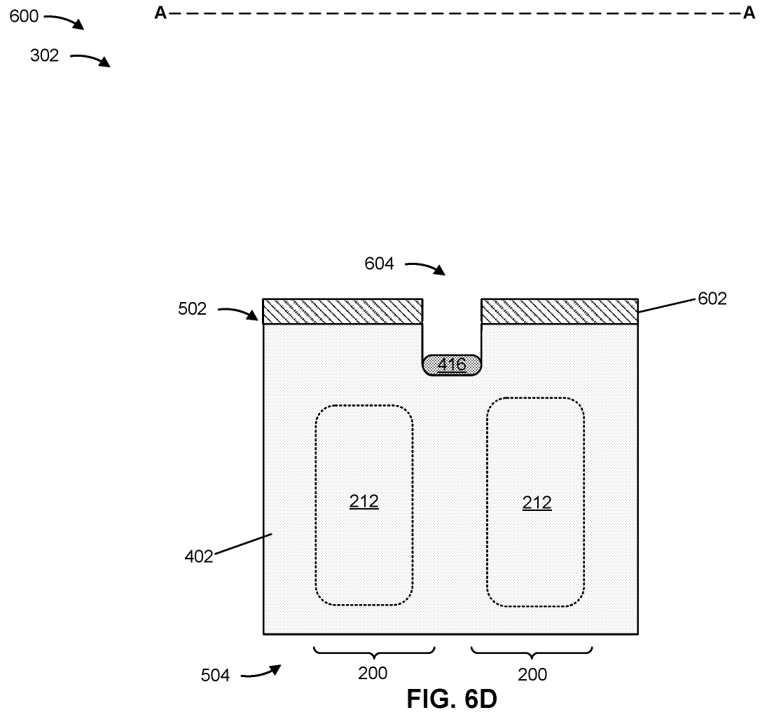

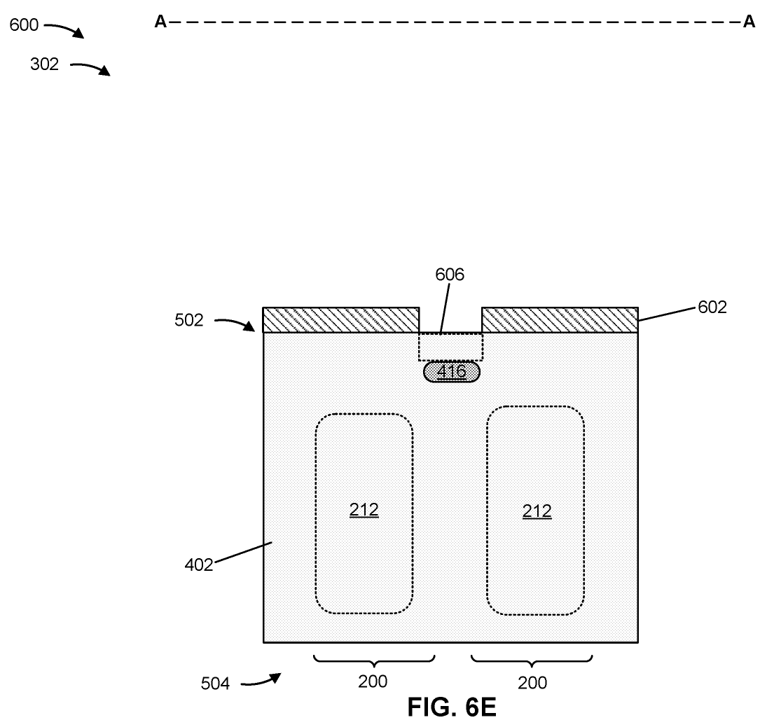

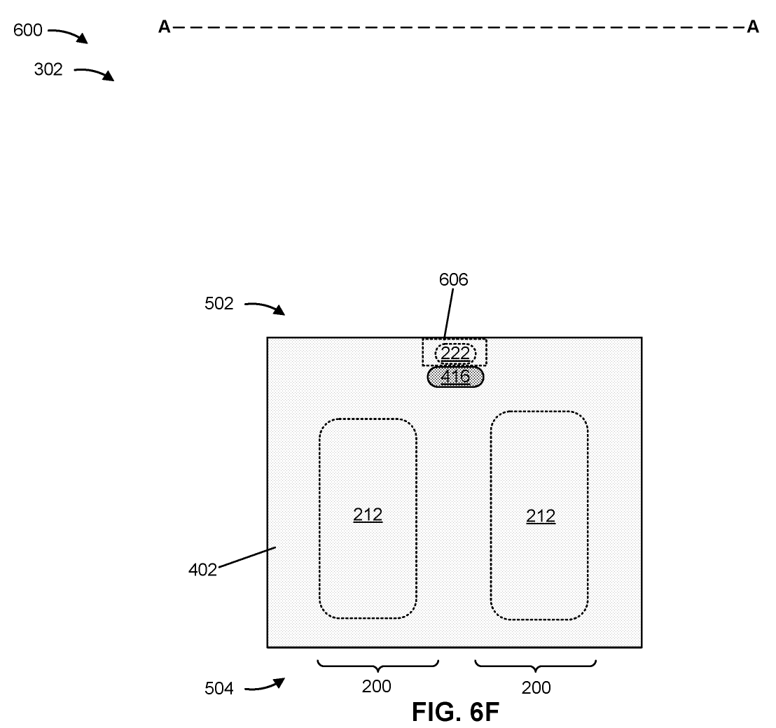

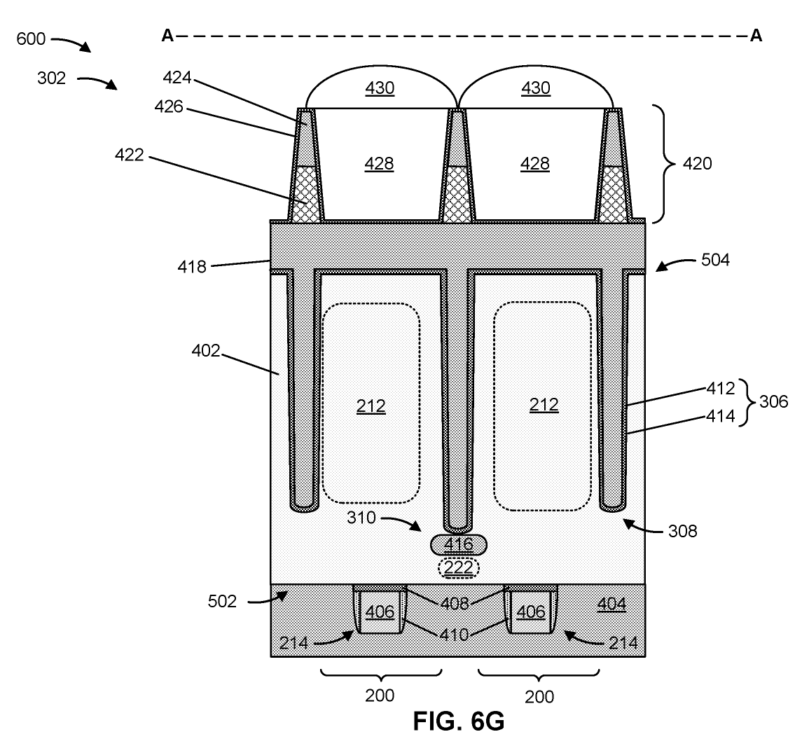

FIGS. 6A-6G are diagrams of an example implementation 600 of forming the pixel sensor array 302 of the image sensor device 304 described herein. FIGS. 6A-6G illustrate cross-section views of the example implementation 600 along the cross-section A-A of the pixel sensor array 302 in FIG. 4A. In some implementations, one or more processing operations described in connection with FIGS. 6A-6G may be performed using one or more of the semiconductor processing tools 102-114 illustrated and described in connection with FIG. 1. In some implementations, one or more processing operations described in connection with FIGS. 6A-6G may be performed using another semiconductor processing tool.

As shown in FIG. 6A, a plurality of regions of the semiconductor layer 402 may be doped to form photodiodes 212 for one or more pixel sensors 200. For example, an ion implantation tool 114 may be used to dope the semiconductor layer 402 to form one or more n-type regions and/or one or more p-type regions of the photodiodes 212. The ion implantation tool 114 may be used to implant p⁺ ions in the semiconductor layer 402 through the frontside surface 502 to form the p-type region(s) and/or may be used to implant n⁺ ions in the semiconductor layer 402 to form the n-type region(s).

As further shown in FIG. 6A, a masking layer 602 may be formed on the frontside surface 502 of the semiconductor layer 402. A deposition tool 102 may be used to deposit the masking layer 602 using a PVD technique, an ALD technique, a CVD technique, a spin-coating technique, an oxidation technique, another type of deposition technique described in connection with FIG. 1, and/or another suitable deposition technique. The masking layer 602 may be deposited in one or more deposition operations. The masking layer 602 may include a photoresist, a hard mask, and/or another type of masking layer.

As further shown in FIG. 6A, a pattern may be formed in the masking layer 602. The pattern may be formed by removing portions of the masking layer 602 to expose portions of the frontside surface 502 of the semiconductor layer 402. An exposure tool 104 may be used to expose the masking layer 506 to a radiation source to pattern the masking layer 602. A developer tool 106 may be used to develop and remove portions of the masking layer 602 to expose the pattern. Additionally and/or alternatively, the pattern may be formed in a photoresist layer, and the pattern may be transferred to the masking layer 602 by etching the masking layer 602 (e.g., using an etch tool 108) based on the pattern in the photoresist layer.

As shown in FIG. 6B, the semiconductor layer 402 may be etched from the frontside surface 502 to form a recess 604 in the semiconductor layer 402. The semiconductor layer 402 may be etched (e.g., using an etch tool 108) to form the recess 604 based on the pattern in the masking layer 602. The semiconductor layer 402 may be etched using a wet etch technique, a dry etch technique, and/or another etch technique.

As shown in FIG. 6C, the recess 604 is filled with the material of a dielectric etch stop structure 416. In some implementations, the recess 604 is fully filled with the material of the dielectric etch stop structure 416 such that the dielectric etch stop structure 416 extends above the frontside surface 502 of the semiconductor layer 402. This reduces the likelihood of void formation in the dielectric etch stop structure 416. A deposition tool 102 may be used to deposit the material of the dielectric etch stop structure 416 using a PVD technique, an ALD technique, a CVD technique, an oxidation technique, another type of deposition technique described in connection with FIG. 1, and/or another suitable deposition technique. The material of the dielectric etch stop structure 416 may be deposited in one or more deposition operations.

As shown in FIG. 6D, an etch-back operation may be performed to remove material from the dielectric etch stop structure 416. This results in the dielectric etch stop structure 416 occupying less than an entirety of the area in the recess 604. The etch-back operation may be performed to reduce the thickness of the dielectric etch stop structure 416 (e.g., to a target thickness or so that the thickness of the dielectric etch stop structure 416 is included in a particular range described herein) and/or to provide sufficient area above the dielectric etch stop structure 416 for formation of a floating diffusion node 222 between the dielectric etch stop structure 416 and the frontside surface 502 of the semiconductor layer 402. The dielectric etch stop structure 416 may be etched using an etch tool 108. The dielectric etch stop structure 416 may be etched using a wet etch technique, a dry etch technique, and/or another etch technique.

As shown in FIG. 6E, a portion 606 of the semiconductor layer 402 may be epitaxially regrown (e.g., using a deposition tool 102) above the dielectric etch stop structure 416 in the recess 604. In some implementations, the sidewalls of the recess 604 (corresponding to the semiconductor layer 402) function as a substrate on which the material of the portion 606 is grown. The portion 606 may regrow laterally from the sidewalls in the recess 604 until the portion 606 coalesces into a continuous region of the semiconductor layer 402.

As shown in FIG. 6F, a floating diffusion node 222 may be formed above the dielectric etch stop structure 416 in the portion 606 of the semiconductor layer 402 that was regrown above the dielectric etch stop structure 416.

As shown in FIG. 6G, the transfer gates 214 (including the gate dielectric layers 408, the gate electrodes 406, and the sidewall spacers 410), the BDTI structure 306 (including the dielectric material 412 and the dielectric liner 414), the buffer layer 418, the composite metal grid 420 (including the metal portion 422, the dielectric portion 424, and/or the liner 426), the color filters 428, and the micro-lenses 430 may be formed. Similar processing operations as illustrated and described in connection with FIGS. 5G-5N may be performed to form these structures.

As indicated above, FIGS. 6A-6G are provided as an example. Other examples may differ from what is described with regard to FIGS. 6A-6G.

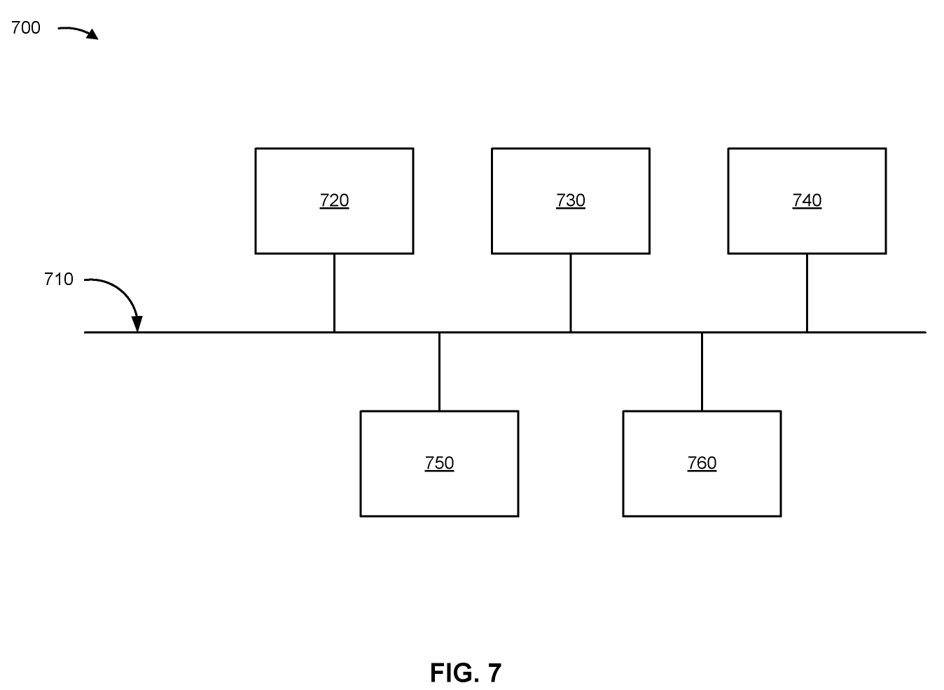

FIG. 7 is a diagram of example components of a device 700 described herein. In some implementations, one or more of the semiconductor processing tools 102-114 and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

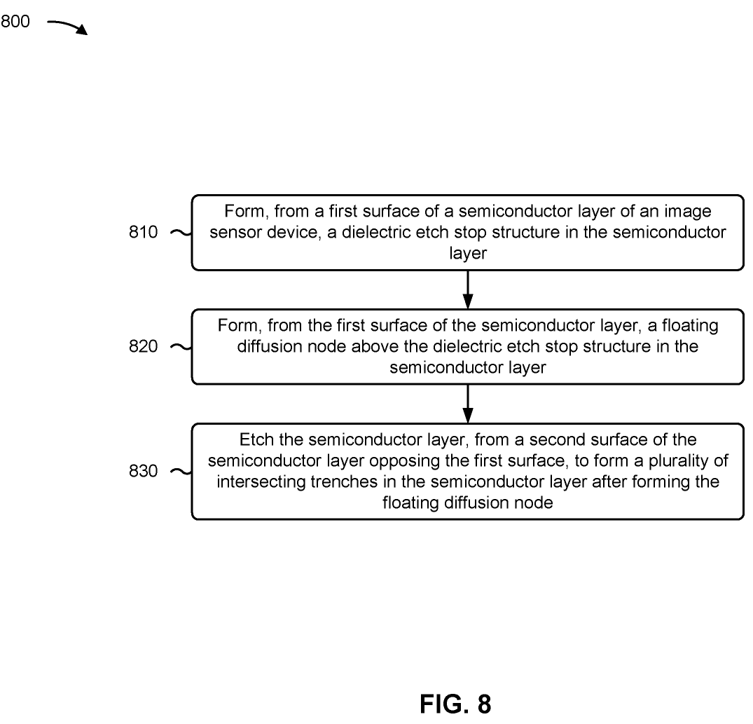

FIG. 8 is a flowchart of an example process 800 associated with forming an image sensor device described herein. In some implementations, one or more process blocks of FIG. 8 are performed using one or more semiconductor processing tools (e.g., one or more of the semiconductor processing tools 102-114). Additionally, or alternatively, one or more process blocks of FIG. 8 may be performed using one or more components of device 700, such as processor 720, memory 730, input component 740, output component 750, and/or communication component 760.

As shown in FIG. 8, process 800 may include forming, from a first surface of a semiconductor layer of an image sensor device, a dielectric etch stop structure in the semiconductor layer (block 810). For example, one or more of the semiconductor processing tools 102-114 may be used to form, from a first surface (e.g., a frontside surface 502) of a semiconductor layer 402 of an image sensor device 304, a dielectric etch stop structure 416 in the semiconductor layer 402, as described herein.

As further shown in FIG. 8, process 800 may include forming, from the first surface of the semiconductor layer, a floating diffusion node above the dielectric etch stop structure in the semiconductor layer (block 820). For example, one or more of the semiconductor processing tools 102-114 may be used to form, from the first surface of the semiconductor layer 402, a floating diffusion node 222 above the dielectric etch stop structure 416 in the semiconductor layer 402, as described herein.

As further shown in FIG. 8, process 800 may include etching the semiconductor layer, from a second surface (e.g., a backside surface 504) of the semiconductor layer opposing the first surface, to form a plurality of intersecting trenches in the semiconductor layer after forming the floating diffusion node (block 830). For example, one or more of the semiconductor processing tools 102-114 may be used to etch the semiconductor layer 402, from a second surface of the semiconductor layer 402 opposing the first surface, to form a plurality of intersecting trenches (e.g., trenches 520, trenches 522) in the semiconductor layer 402 after forming the floating diffusion node 222, as described herein. In some implementations, two or more of the intersecting trenches intersect in a cross-road portion 310 above the dielectric etch stop structure 416 and above the floating diffusion node 222. In some implementations, the etching of the semiconductor layer 402 stops on the dielectric etch stop structure 416 in the cross-road portion 310.

Process 800 may include additional implementations, such as any single implementation or any combination of implementations described below and/or in connection with one or more other processes described elsewhere herein.

In a first implementation, forming the dielectric etch stop structure 416 includes performing an ion implantation operation to form the dielectric etch stop structure 416 below the first surface of the semiconductor layer 402.

In a second implementation, alone or in combination with the first implementation, performing the ion implantation operation includes performing the ion implantation operation to implant oxygen ions in the semiconductor layer 402 to form the dielectric etch stop structure 416.

In a third implementation, alone or in combination with one or more of the first and second implementations, performing the ion implantation operation includes performing the ion implantation operation to form a plurality of implant regions 508 in the semiconductor layer 402.

In a fourth implementation, alone or in combination with one or more of the first through third implementations, forming the dielectric etch stop structure 416 includes performing a thermal operation to anneal the plurality of implant regions 508 to form the dielectric etch stop structure 416 from the plurality of implant regions 508.

In a fifth implementation, alone or in combination with one or more of the first through fourth implementations, forming the dielectric etch stop structure 416 includes forming the dielectric etch stop structure 416 in a recess 604 in the first surface of the semiconductor layer 402.

In a sixth implementation, alone or in combination with one or more of the first through fifth implementations, process 800 includes epitaxially regrowing a portion 606 of the semiconductor layer 402 on the dielectric etch stop structure 416 in the recess 604 after forming the dielectric etch stop structure 416.

In a seventh implementation, alone or in combination with one or more of the first through sixth implementations, forming the floating diffusion node 222 includes forming at least a portion of the floating diffusion node 222 in the portion 606 of the semiconductor layer 402 that was epitaxially regrown above the dielectric etch stop structure 416.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

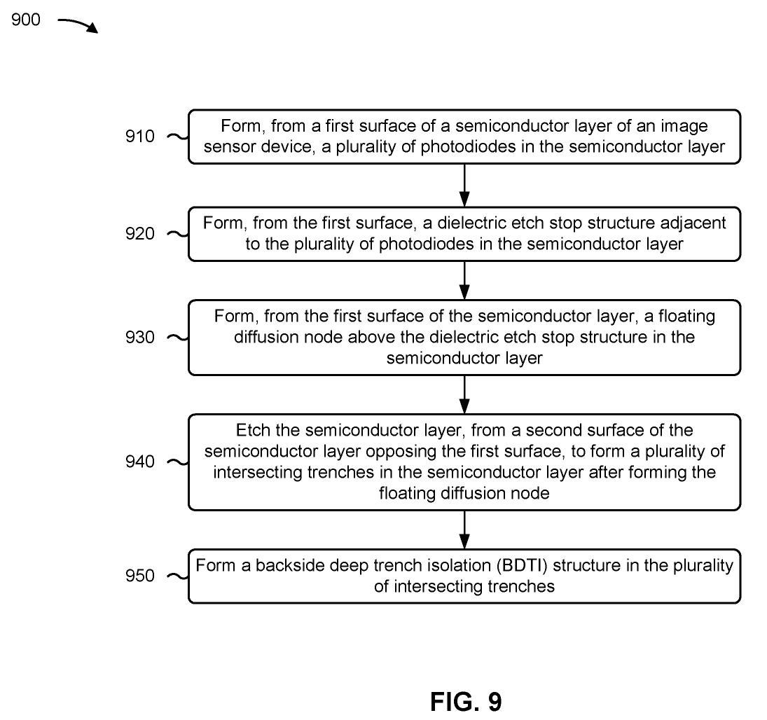

FIG. 9 is a flowchart of an example process 900 associated with image sensor device and methods of formation. In some implementations, one or more process blocks of FIG. 9 are performed using one or more semiconductor processing tools (e.g., one or more of the semiconductor processing tools 102-114). Additionally, or alternatively, one or more process blocks of FIG. 9 may be performed using one or more components of device 700, such as processor 720, memory 730, input component 740, output component 750, and/or communication component 760.

As shown in FIG. 9, process 900 may include forming, from a first surface of a semiconductor layer of an image sensor device, a plurality of photodiodes in the semiconductor layer (block 910). For example, one or more of the semiconductor processing tools 102-114 may be used to form, from a first surface (e.g., a frontside surface 502) of a semiconductor layer 402 of an image sensor device 304, a plurality of photodiodes 212 in the semiconductor layer 402, as described herein.

As further shown in FIG. 9, process 900 may include forming, from the first surface, a dielectric etch stop structure adjacent to the plurality of photodiodes in the semiconductor layer (block 920). For example, one or more of the semiconductor processing tools 102-114 may be used to form, from the first surface, a dielectric etch stop structure 416 adjacent to the plurality of photodiodes 212 in the semiconductor layer 402, as described herein. In some implementations, a distance (e.g., the dimension D4) between the dielectric etch stop structure 416 and the first surface is less than a distance (e.g., the dimension D7) between the plurality of photodiodes 212 and the first surface.

As further shown in FIG. 9, process 900 may include forming, from the first surface of the semiconductor layer, a floating diffusion node above the dielectric etch stop structure in the semiconductor layer (block 930). For example, one or more of the semiconductor processing tools 102-114 may be used to form, from the first surface of the semiconductor layer 402, a floating diffusion node 222 above the dielectric etch stop structure 416 in the semiconductor layer 402, as described herein.

As further shown in FIG. 9, process 900 may include etching the semiconductor layer, from a second surface of the semiconductor layer opposing the first surface, to form a plurality of intersecting trenches in the semiconductor layer after forming the floating diffusion node (block 940). For example, one or more of the semiconductor processing tools 102-114 may be used to etch the semiconductor layer 402, from a second surface (e.g., a backside surface 504) of the semiconductor layer 402 opposing the first surface, to form a plurality of intersecting trenches (e.g., trenches 520, trenches 522) in the semiconductor layer 402 after forming the floating diffusion node 222, as described herein. In some implementations, two or more of the intersecting trenches intersect in a cross-road portion 310 above the dielectric etch stop structure 416 and above the floating diffusion node 222. In some implementations, the etching of the semiconductor layer 402 stops on the dielectric etch stop structure 416 in the cross-road portion 310.

As further shown in FIG. 9, process 900 may include forming a BDTI structure in the plurality of intersecting trenches (block 950). For example, one or more of the semiconductor processing tools 102-114 may be used to form a BDTI structure 306 in the plurality of intersecting trenches, as described herein. In some implementations, a portion of the BDTI structure 306, in the cross-road portion 310, is formed on the dielectric etch stop structure 416.

Process 900 may include additional implementations, such as any single implementation or any combination of implementations described below and/or in connection with one or more other processes described elsewhere herein.

In a first implementation, forming the dielectric etch stop structure 416 includes forming, from the first surface of the semiconductor layer 402, a recess 604 in the semiconductor layer 402, and depositing the dielectric etch stop structure 416 in the recess 604.

In a second implementation, alone or in combination with the first implementation, depositing the dielectric etch stop structure 416 in the recess 604 includes fully filling the recess with the dielectric etch stop structure 416.

In a third implementation, alone or in combination with one or more of the first and second implementations, forming the dielectric etch stop structure 416 includes performing an etch-back operation to remove a portion of the dielectric etch stop structure 416 such that the dielectric etch stop structure 416 occupies less than an entirety of the recess 604.

In a fourth implementation, alone or in combination with one or more of the first through third implementations, process 900 includes epitaxially regrowing a portion 606 of the semiconductor layer 402 on the dielectric etch stop structure 416 in the recess 604 after forming the dielectric etch stop structure 416.

In a fifth implementation, alone or in combination with one or more of the first through fourth implementations, forming the dielectric etch stop structure 416 includes performing an ion implantation operation to form the dielectric etch stop structure 416 below the first surface of the semiconductor layer 402.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, dielectric regions are formed in a semiconductor substrate of a semiconductor device. The dielectric regions may be formed in locations above which cross-road portions of a BDTI structure are to be formed for a pixel sensor array of the semiconductor device. The dielectric regions may function as etch stop structures in the cross-road portions when etching the semiconductor substrate to form the trenches in which the BDTI structure is to be formed. In particular, the dielectric regions minimize and/or prevent the increase in trench depth of the trenches in the cross-road portions relative to the trench depth of the trenches in the non-cross-road portions. In this way, the dielectric regions reduce and/or minimize trench depth loading in the cross-road portions of the trenches. Thus, the dielectric regions prevent, minimize, and/or reduce the likelihood of etching into floating diffusion nodes of pixel sensors of the pixel sensor array, which reduces the likelihood of degraded performance and/or failure of the pixel sensors.

As described in greater detail above, some implementations described herein provide a method. The method includes forming, from a first surface of a semiconductor layer of an image sensor device, a dielectric etch stop structure in the semiconductor layer. The method includes forming, from the first surface of the semiconductor layer, a floating diffusion node above the dielectric etch stop structure in the semiconductor layer. The method includes etching the semiconductor layer, from a second surface of the semiconductor layer opposing the first surface, to form a plurality of intersecting trenches in the semiconductor layer after forming the floating diffusion node, where two or more of the intersecting trenches intersect in a cross-road portion above the dielectric etch stop structure and the floating diffusion node, and where the etching of the semiconductor layer stops on the dielectric etch stop structure in the cross-road portion.

As described in greater detail above, some implementations described herein provide a method. The method includes forming, from a first surface of a semiconductor layer of an image sensor device, a plurality of photodiodes in the semiconductor layer. The method includes forming, from the first surface, a dielectric etch stop structure adjacent to the plurality of photodiodes in the semiconductor layer, where a distance between the dielectric etch stop structure and the first surface is less than a distance between the plurality of photodiodes and the first surface. The method includes forming, from the first surface of the semiconductor layer, a floating diffusion node above the dielectric etch stop structure in the semiconductor layer. The method includes etching the semiconductor layer, from a second surface of the semiconductor layer opposing the first surface, to form a plurality of intersecting trenches in the semiconductor layer after forming the floating diffusion node, where two or more of the intersecting trenches intersect in a cross-road portion above the dielectric etch stop structure and the floating diffusion node, and where the etching of the semiconductor layer stops on the dielectric etch stop structure in the cross-road portion. The method includes forming a BDTI structure in the plurality of intersecting trenches, where a portion of the BDTI structure, in the cross-road portion, is formed on the dielectric etch stop structure.

As described in greater detail above, some implementations described herein provide an image sensor device. The image sensor device includes a plurality of pixel sensors. The image sensor device includes a BDTI structure at least laterally surrounding a photodiode of a pixel sensor of the plurality of pixel sensors, where the BDTI structure is included partially through a semiconductor layer of the image sensor device between a front side of the semiconductor layer and a backside of the semiconductor layer. The image sensor device includes a dielectric etch stop structure under a cross-road portion of the BDTI structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor device, comprising:
a semiconductor layer having a frontside surface and a backside surface;
a plurality of pixel sensors in the semiconductor layer;
a backside deep trench isolation (BDTI) structure extending from the backside surface partially through the semiconductor layer toward the frontside surface and including a plurality of intersecting portions that define a cross-road portion; and
a dielectric etch stop structure embedded in the semiconductor layer between the cross-road portion and the frontside surface.

2. The image sensor device of claim 1, wherein the BDTI structure at least laterally surrounds a photodiode of at least one pixel sensor of the plurality of pixel sensors.

3. The image sensor device of claim 1, wherein the cross-road portion is located at an intersection between corners of at least three pixel sensors of the plurality of pixel sensors.

4. The image sensor device of claim 1, wherein a width of the dielectric etch stop structure is in a range from approximately200 nanometers to approximately 250nanometers.

5. The image sensor device of claim 1, wherein a thickness of the dielectric etch stop structure is in a range from approximately 50 nanometers to approximately 200nanometers.

6. The image sensor device of claim 1, wherein the dielectric etch stop structure comprises silicon oxide, silicon nitride, silicon carbide, hafnium oxide, or silicon oxynitride.

7. The image sensor device of claim 1, wherein a bottom portion of the BDTI structure in the cross-road portion extends into a portion of the dielectric etch stop structure.

8. An image sensor device, comprising:
a semiconductor layer having a frontside surface and a backside surface;
a plurality of pixel sensors in the semiconductor layer, the plurality of pixel sensors including a plurality of photodiodes;
a backside deep trench isolation (BDTI) structure extending from the backside surface partially through the semiconductor layer toward the frontside surface, the BDTI structure including:
a plurality of portions that laterally surround respective photodiodes of the plurality of photodiodes; and
a cross-road portion at an intersection of two or more portions of the plurality of portions;
a floating diffusion node in the semiconductor layer between the cross-road portion and the frontside surface; and
a dielectric etch stop structure embedded in the semiconductor layer between the cross-road portion and the floating diffusion node.

9. The image sensor device of claim 8, wherein the floating diffusion node comprises a highly doped n-type region of the semiconductor layer.

10. The image sensor device of claim 8, wherein the cross-road portion is fully within a perimeter of the dielectric etch stop structure.

11. The image sensor device of claim 8, wherein the floating diffusion node is fully within a perimeter of the dielectric etch stop structure.

12. The image sensor device of claim 8, wherein the BDTI structure comprises:
a dielectric material; and
a dielectric liner between the dielectric material and the semiconductor layer.

13. The image sensor device of claim 8, wherein the BDTI structure further includes a plurality of non-cross-road portions extending between adjacent pixel sensors of the plurality of pixel sensors, and
wherein a depth of the BDTI structure from the backside surface is greater at the cross-road portion than at the plurality of non-cross-road portions.

14. The image sensor device of claim 8, further comprising:
a transfer gate on the frontside surface of the semiconductor layer,
wherein the transfer gate is configured to control a transfer of a photocurrent from a photodiode of the plurality of photodiodes to the floating diffusion node.

15. A pixel sensor array, comprising:
a semiconductor layer having a frontside surface and a backside surface;
a plurality of pixel sensors arranged in a grid in the semiconductor layer;
a backside deep trench isolation (BDTI) structure extending from the backside surface partially through the semiconductor layer toward the frontside surface, the BDTI structure including:
a plurality of non-cross-road portions extending between adjacent pixel sensors of the plurality of pixel sensors; and
a cross-road portion located at an intersection between corners of at least three pixel sensors of the plurality of pixel sensors;
a floating diffusion node in the semiconductor layer between the cross-road portion and the frontside surface; and
a dielectric etch stop structure embedded in the semiconductor layer between the cross-road portion and the floating diffusion node,
wherein the cross-road portion is fully within a perimeter of the dielectric etch stop structure.

16. The pixel sensor array of claim 15, wherein each pixel sensor of the plurality of pixel sensors includes a photodiode, and
wherein the BDTI structure laterally surrounds the photodiodes of the plurality of pixel sensors.

17. The pixel sensor array of claim 15, wherein a width of the dielectric etch stop structure is in a range from approximately 200 nanometers to approximately 250 nanometers.

18. The pixel sensor array of claim 15, wherein a thickness of the dielectric etch stop structure is in a range from approximately 50 nanometers to approximately 200nanometers.

19. The pixel sensor array of claim 15, wherein a bottom portion of the BDTI structure in the cross-road portion extends into a portion of the dielectric etch stop structure.

20. The pixel sensor array of claim 15, wherein the dielectric etch stop structure comprises an oxide of a semiconductor material of the semiconductor layer.
